(19) United States
(12) Patent Application Publication
(10) Pub. No.: US 2024/0238934 A1
(43) Pub. Date: Jul. 18, 2024

(54) POLISHING APPARATUS AND POLISHING METHOD

(71) Applicant: EBARA CORPORATION, Tokyo (JP)

(72) Inventor: Shinro OTA, Tokyo (JP)

(21) Appl. No.: 18/557,069

(22) PCT Filed: Apr. 11, 2022
(86) PCT No.: PCT/JP2022/017484

§ 371 Date: Oct. 25, 2023

(30) Foreign Application Priority Data
Apr. 28, 2021 (JP) 2021-076022
Apr. 28, 2021 (JP) 2021-076023
Mar. 23, 2022 (JP) 2022-046364

(51) Int. Cl. B24B 37/013

(52) U.S. Cl. CPC B24B 37/013

(57) ABSTRACT

The present invention relates to a polishing apparatus and a polishing method. The polishing apparatus includes an operation controller (9) configured to control a pressure in each of a plurality of pressure chambers. The operation controller (9) is configured to control the pressure in the pressure chamber of the polishing head (1) corresponding to a specific position so that a difference between a control target film thickness value and an average film thickness value of the entire substrate is reduced.

### TECHNICAL FIELD

The present invention relates to a polishing apparatus and a polishing method.

### BACKGROUND ART

A chemical mechanical polishing (CMP: Chemical Mechanical Polishing) is known as a technique used in a manufacturing process of semiconductor devices. A polishing apparatus for performing CMP includes a polishing table that supports a polishing pad and a polishing head that holds a wafer.

When polishing the wafer using such a polishing apparatus, the wafer is held by the polishing head and pressed against a polishing surface of the polishing pad with a predetermined pressure. At this time, the wafer slides into contact with the polishing surface by relatively moving the polishing table and the polishing head, and the surface of the wafer is polished.

Furthermore, a signal corresponding to the film thickness of the wafer is detected by a film thickness sensor to obtain the film thickness distribution of the wafer. Based on the film thickness distribution of the wafer, an end point of polishing is determined, and a pressure of a plurality of airbags provided concentrically in the polishing head is controlled. The film thickness sensor rotates together with the polishing table, and the polishing head that holds the wafer also rotates.

Therefore, a path of movement of the film thickness sensor across the surface of the wafer is different each time the polishing table rotates. As an index value for controlling the pressure of each airbag, the film thicknesses measured at different measurement points of each concentric airbag are usually averaged, and a value representative of the film thickness within each airbag is calculated. The film thickness distribution of the wafer is calculated as an averaged value in a circumferential direction based on signals obtained from different measurement points on the circumference.

### CITATION LIST

### Patent Literature

Patent document 1: International Patent Publication No. WO 2015/163164
Patent document 2: Japanese laid-open patent publication No. 2005-11977

### SUMMARY OF INVENTION

### Technical Problem

In recent years, a degree of uniformity of film thickness that is required has increased. Within the region of the wafer corresponding to one of the airbags arranged concentrically, the film thickness varies greatly in a radial direction of the wafer. Even if the pressure of the airbag corresponding to that region is adjusted, it is not possible to achieve a certain level of improvement in film thickness uniformity.

In recent years, the degree of uniformity of film thickness that is required has increased. Therefore, it has become necessary to manage and control the polishing process by taking into account variations in an initial film thickness of the wafer in the circumferential direction due to the characteristics of the film forming apparatus, as well as variations in the amount of polishing in the circumferential direction caused by polishing. For example, it is effective to improve the uniformity of the wafer's film thickness by actively polishing areas of the wafer where the film is thick, or actively polishing areas other than areas where the wafer's film is thin. Further, with the conventional method, it may be difficult to keep a difference between the maximum film thickness and the minimum film thickness within the wafer plane within an allowable range.

Therefore, the present invention provides a polishing apparatus and a polishing method that can improve the uniformity of the film thickness of the wafer.

### Solution to Problem

In an embodiment, there is provided a polishing apparatus, comprising: a polishing table supporting a polishing pad; a polishing head having a plurality of concentrically divided pressure chambers, for pressing a substrate against the polishing surface of the polishing pad; a plurality of pressure regulators coupled to the pressure chambers; a film thickness sensor embedded in the polishing table, the film thickness sensor being configured to output a signal corresponding to a film thickness of the substrate; and an operation controller configured to control a pressure of each of the pressure chambers individually through the pressure regulators, the operation controller is configured to: obtain information related to a specific position, which is a part of a circumference of the substrate, and calculate a control target film thickness value in a control target area including the specific position and an average film thickness value of the entire substrate; and control the pressure in the pressure chamber of the polishing head corresponding to the specific position so that a difference between the control target film thickness value and the average film thickness value of the entire substrate is reduced.

In an embodiment, the operation controller is configured to identify the specific position based on a film thickness of the substrate measured before polishing.

In an embodiment, the operation controller is configured to: determine a maximum film thickness position at which a maximum film thickness value is obtained and a minimum film thickness position at which a minimum film thickness value is obtained, based on a film thickness of the substrate measured before polishing; and determine at least one of the maximum film thickness position and the minimum film thickness position as the specific position.

In an embodiment, the operation controller is configured to: determine a maximum film thickness value and a minimum film thickness value based on the film thickness of the substrate measured before polishing; calculate a difference between the average film thickness value of the entire substrate and the maximum film thickness value, and a difference between the average film thickness value of the entire substrate and the minimum film thickness value; and determine a position on the substrate where the film thickness value with a largest difference is obtained as the specific position.

In an embodiment, the control target film thickness value corresponds to at least one of the maximum film thickness value and the minimum film thickness value determined based on the film thickness of the substrate measured before polishing.

In an embodiment, the control target film thickness value is an average value of the film thickness values within the control target area.

In an embodiment, the operation controller is configured to: measure a film thickness of the control target area including the specific position during polishing based on the signal output from the film thickness sensor; and control the pressure in the pressure chamber of the polishing head corresponding to the specific position based on the measured film thickness.

In an embodiment, the operation controller is configured to: divide a plurality of pressing areas on the substrate divided corresponding to the pressure chambers into a specific pressing area including the control target area and an other pressing area excluding the specific pressure area; calculate an average film thickness value in the other pressing area based on the film thickness of the substrate; and control the pressure in the pressure chamber corresponding to the other pressing area so that a difference between the average film thickness value in the other pressing area and the average film thickness value of the entire substrate is reduced.

In an embodiment, the operation controller is configured to: obtain information related to a reference position, which is a part of the circumference of a reference substrate that is different from the substrate; detect physical quantities corresponding to the film thickness of an area on the substrate including the reference position by the film thickness sensor during polishing of the reference substrate; obtain a plurality of data corresponding to the film thickness of the reference substrate based on a plurality of signals sent from the film thickness sensor; and associate each of data with the film thickness of the reference substrate when obtaining each of data.

In an embodiment, the operation controller is configured to determine the reference position based on the film thickness of the reference substrate measured before polishing.

In an embodiment, the operation controller is configured to control at least one of a rotational speed of the polishing head and a rotational speed of the polishing table so that the film thickness sensor crosses the control target area.

In an embodiment, the operation controller is configured to: determine a reference position and a relative angle of the polishing head based on a relationship between the reference position of a circumferential angle of the substrate and the rotational angle of the polishing head; and control at least one of the rotational speed of the polishing head and the rotational speed of the polishing table based on the determined relative angle.

In an embodiment, there is provided a polishing method of pressing a substrate on a polishing surface of a polishing pad by a polishing head having a plurality of concentrically divided pressure chambers, comprising: obtaining information related to a specific position, which is a part of a circumference of the substrate, and calculating a control target film thickness value in a control target area including the specific position and an average film thickness value of the entire substrate; controlling a pressure in the pressure chamber of the polishing head corresponding to the specific position so that a difference between the target film thickness value and the average film thickness value of the entire substrate is reduced.

In an embodiment, identifying the specific position based on a film thickness of the substrate measured before polishing.

In an embodiment, determining a maximum film thickness position at which a maximum film thickness value is obtained and a minimum film thickness position at which a minimum film thickness value is obtained based on a film thickness of the substrate measured before polishing; and determining at least one of the maximum film thickness position and the minimum film thickness position as the specific position.

In an embodiment, determining a maximum film thickness value and a minimum film thickness value based on a film thickness of the substrate measured before polishing; calculating a difference between the average film thickness value of the entire substrate and the maximum film thickness value, and a difference between the average film thickness value of the entire substrate and the minimum film thickness value; and determining a position on the substrate where the film thickness value with a largest difference is obtained as the specific position.

In an embodiment, the control target film thickness value corresponds to at least one of a maximum film thickness value and a minimum film thickness value determined based on a film thickness of the substrate measured before polishing.

In an embodiment, the control target film thickness value is an average value of the film thickness values within the control target area.

In an embodiment, measuring a film thickness of the control target area including the specific position during polishing based on an output signal of the film thickness sensor; and controlling a pressure in the pressure chamber of the polishing head corresponding to the specific position based on the measured film thickness.

In an embodiment, dividing a plurality of pressing areas on the substrate divided corresponding to the pressure chambers into a specific pressing area including the control target area and another pressing area excluding the specific pressing area; calculating an average film thickness value in the other pressing area based on the film thickness of the substrate; and controlling the pressure in the pressure chamber corresponding to the other pressure area so that a difference between the average film thickness value in the other pressure area and the average film thickness value of the entire substrate is reduced.

In an embodiment, obtaining information related to a reference position, which is a part of a circumference of a reference substrate that is different from the substrate; detecting physical quantities corresponding to a film thickness of an area on the substrate including the reference position by the film thickness sensor during polishing of the reference substrate; obtaining a plurality of data corresponding to the film thickness of the reference substrate based on a plurality of signals sent from the film thickness sensor; and associating each of data with the film thickness of the reference substrate when obtaining each of data.

In an embodiment, determining the reference position based on the film thickness of the reference substrate measured before polishing.

In an embodiment, controlling at least one of a rotational speed of the polishing head and a rotational speed of the polishing table so that the film thickness sensor crosses the control target area by rotating of the polishing table that supports the polishing pad.

In an embodiment, determining a reference position and a relative angle of the polishing head based on a relationship between the reference position of a circumferential angle of the substrate and a rotational angle of the polishing head; and controlling at least one of the rotational speed of the polishing head and the rotational speed of the polishing table based on the determined relative angle.

In an embodiment, there is provided a polishing apparatus, comprising: a polishing table supporting a polishing pad; a polishing head having a plurality of concentrically divided pressure chambers, for pressing a substrate against a polishing surface of the polishing pad; a plurality of pressure regulators coupled to the pressure chambers; a film thickness sensor embedded in the polishing table, the film thickness sensor outputting a signal corresponding to a film thickness of the substrate; and an operation controller configured to control a pressure of each of the pressure chambers individually through the pressure regulators, the operation controller is configured to: identifying a maximum film thickness value and a minimum film thickness value from the film thickness of the substrate obtained during polishing of the substrate by the film thickness sensor; identifying at least one of a pressure chamber corresponding to a position of the substrate at which the maximum film thickness value is detected and a pressure chamber corresponding to a position of the substrate at which the minimum film thickness value is detected; controlling the pressure of the pressure chamber associated with the maximum film thickness value so that the average film thickness value of the substrate corresponding to the pressure chamber associated with the maximum film thickness value is less than the average film thickness value of the entire substrate when controlling the pressure of the pressure chamber associated with the maximum film thickness value; and controlling the pressure of the pressure chamber associated with the minimum film thickness value so that the average film thickness value of the substrate corresponding to the pressure chamber associated with the minimum film thickness value is higher than the average film thickness value of the entire substrate when controlling the pressure of the pressure chamber associated with the minimum film thickness value.

In an embodiment, the operation controller is configured to identify the maximum film thickness value and the minimum film thickness value based on the film thickness of the substrate obtained at regular time intervals during polishing the substrate.

In an embodiment, the operation controller is configured to: calculating a polishing speed during polishing from the film thickness of the substrate obtained by the film thickness sensor; calculating the amount of change in the film thickness of the substrate between an obtaining time when the film thickness of the substrate is obtained by the film thickness sensor at each measurement point of the substrate and a reference time, based on the polishing speed; correcting the film thickness of the substrate obtained during polishing of the substrate in the time intervals using the amount of change as a correction value; and identifying the maximum film thickness value and the minimum film thickness value based on the corrected film thickness of the substrate.

In an embodiment, the operation controller is configured to determine in advance by a recipe setting whether to control the pressure of the pressure chamber associated with the maximum film thickness value so that the average thickness value of the substrate corresponding to the pressure chamber associated with the maximum thickness value is less than the average thickness value of the entire substrate, or to control the pressure of the pressure chamber associated with the minimum film thickness value so that the average thickness value of the substrate corresponding to the pressure chamber associated with the minimum film thickness value is higher than the average thickness value of the entire substrate, when the pressure chamber associated with the maximum film thickness value and the pressure chamber associated with the minimum film thickness value are the same pressure chamber.

In an embodiment, the operation controller is configured to: compare a first difference between the maximum film thickness value and the average film thickness value of the entire substrate and a second difference between the minimum film thickness value and the average film thickness value of the entire substrate when the pressure chamber associated with the maximum film thickness value and the pressure chamber associated with the minimum film thickness value are the same pressure chamber; control the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and control the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

In an embodiment, the operation controller is configured to: compare a first difference between the maximum film thickness value and an average film thickness value in a pressing area corresponding to the maximum film thickness value and the second difference between the minimum film thickness value and the average film thickness value in the pressing area corresponding to the minimum film thickness value when the pressure chamber associated with the maximum film thickness value and the pressure chamber associated with the minimum film thickness value are the same pressure chamber; control the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and control the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

In an embodiment, there is provided a polishing method of pressing a substrate on a polishing surface of a polishing pad by a polishing head having a plurality of concentrically divided pressure chambers, comprising: identifying a maximum film thickness value and a minimum film thickness value from a film thickness of the substrate obtained during polishing of the substrate; identifying at least one of a pressure chamber corresponding to a position of the substrate at which the maximum film thickness value is detected and a pressure chamber corresponding to a position of the substrate at which the minimum film thickness value is detected; controlling the pressure of the pressure chamber associated with the maximum film thickness value so that the average film thickness value of the substrate corresponding to the pressure chamber associated with the maximum film thickness value is less than the average film thickness value of the entire substrate when controlling the pressure of the pressure chamber associated with the maximum film thickness value; and controlling the pressure of the pressure chamber associated with the minimum film thickness value so that the average film thickness value of the substrate corresponding to the pressure chamber associated with the minimum film thickness value is higher than the average film thickness value of the entire substrate when controlling the pressure of the pressure chamber associated to the minimum film thickness value.

In an embodiment, identifying the maximum film thickness value and the minimum film thickness value based on the film thickness of the substrate obtained at regular time intervals during polishing the substrate.

In an embodiment, calculating a polishing speed during polishing from the film thickness of the substrate; calculating the amount of change in the film thickness of the substrate between an obtaining time when the film thickness of the substrate is obtained at each measurement point of the substrate and a reference time, based on the polishing speed; correcting the film thickness of the substrate obtained during polishing of the substrate in the time intervals using the amount of change as a correction value; and identifying the maximum film thickness value and the minimum film thickness value based on the corrected film thickness of the substrate.

In an embodiment, determining in advance by a recipe setting whether to control the pressure of the pressure chamber associated with the maximum film thickness value so that the average thickness value of the substrate corresponding to the pressure chamber associated with the maximum thickness value is less than the average thickness value of the entire substrate when the pressure chamber associated with the maximum film thickness value and the pressure chamber associated with the minimum film thickness value are the same pressure chamber, or to control the pressure of the pressure chamber associated with the minimum film thickness value so that the average thickness value of the substrate corresponding to the pressure chamber associated with the minimum film thickness value is higher than the average thickness value of the entire substrate.

In an embodiment, comparing a first difference between the maximum film thickness value and the average film thickness value of the entire substrate and a second difference between the minimum film thickness value and the average film thickness value of the entire substrate when the pressure chamber associated with the maximum film thickness value and the pressure chamber associated with the minimum film thickness value are the same pressure chamber; controlling the pressure of the pressure chamber associated with the maximum film thickness value so that the average film thickness value of the substrate corresponding to the pressure chamber associated with the maximum film thickness value is higher than the average film thickness value of the entire substrate when the first difference is higher than the second difference; and controlling the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

In an embodiment, comparing a first difference between the maximum film thickness value and an average film thickness value in the pressing area corresponding to the maximum film thickness value and the second difference between the minimum film thickness value and the average film thickness value in the pressing area corresponding to the minimum film thickness value when the pressure chamber associated with the maximum film thickness value and the pressure chamber associated with the minimum film thickness value are the same pressure chamber; controlling the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and controlling the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

In an embodiment, there is provided a polishing method of pressing a substrate against a polishing surface of a polishing pad by a polishing head having a plurality of pressure chambers including a specific pressure chamber, comprising: a first polishing process of polishing the substrate under a first polishing condition; and a second polishing process of polishing the substrate under a second polishing condition determined based on a first polishing profile along a radial direction of a specific area of the substrate corresponding to the specific pressure chamber, which is obtained by previously polishing a substrate different from the substrate under the first polishing condition, the second polishing condition comprises a polishing condition determined in advance to form a second polishing profile having a distribution opposite to the distribution of the first polishing profile, and the second polishing process is performed after the first polishing process.

In an embodiment, the specific pressure chamber comprises an edge pressure chamber configured to press against an outermost periphery of the substrate.

In an embodiment, the second polishing condition comprises a polishing condition determined by adjusting the pressure of a pressure chamber other than the specific pressure chamber.

In an embodiment, the second polishing condition comprises a polishing condition determined by adjusting the pressure of adjacent pressure chamber adjacent to an edge pressure chamber configured to press an outermost periphery of the substrate.

In an embodiment, the second polishing condition comprises a polishing condition determined by adjusting a pressing force of a retaining ring arranged around an outermost periphery of the substrate against the polishing surface.

In an embodiment, the first polishing condition comprises a polishing condition of polishing the substrate while feedback controlling the pressure of each of the pressure chambers based on the film thickness of the substrate corresponding to each of the pressure chambers, measured using a film thickness sensor, during polishing.

In an embodiment, polishing the substrate under the first polishing condition, and polishing the substrate under the second polishing condition after meeting a predetermined switching condition.

In an embodiment, switching from the first polishing condition to the second polishing condition, as the switching condition, when a difference between a maximum value and a minimum value of the film thicknesses in the specific area is larger than a predetermined threshold value.

In an embodiment, switching from the first polishing condition to the second polishing condition, as the switching condition, based on a time required to resolve a difference between a maximum value and a minimum value of the film thickness in the specific area by polishing under the second polishing condition and a remaining polishing time to a final target film thickness.

In an embodiment, the specific pressure chamber comprises an edge pressure chamber configured to press on an outermost periphery of the substrate, and comprising controlling the pressure of the edge pressure chamber based on the second polishing condition, and controlling the pressure of an other pressure chamber except the edge pressure chamber based on the first polishing condition.

### Advantageous Effects of Invention

By controlling the pressure in the pressure chamber of the polishing head corresponding to a control target area including a specific position for flattening the film thickness of the wafer, the uniformity of the film thickness of the wafer can be improved.

The polishing method includes a second polishing process of polishing the substrate under the second polishing condition. By polishing the substrate in the second polishing process, the uniformity of the film thickness in the specific area of the wafer can be improved.

### BRIEF DESCRIPTION OF DRAWINGS

FIG. 1 is a schematic view showing one embodiment of a polishing apparatus;

FIG. 2 is a cross sectional view of a polishing head;

FIG. 3 is a view showing an example of a spectrum generated by an operation controller;

FIG. 4 is a view showing an example of processes of obtaining a plurality of reference spectra;

FIG. 5 is a view showing a plurality of pressing areas of a wafer divided corresponding to a plurality of pressure chambers;

FIG. 6 is a view showing a polishing profile of a wafer when the wafer is polished under a first polishing condition;

FIG. 7 is a view showing a second polishing condition;

FIG. 8 is a view showing a polishing rate of the wafer polished under a first polishing condition and a second polishing condition;

FIG. 9 is a view showing an example of processes of polishing the wafer to be polished;

FIG. 10 is a view showing an example of the process of associating a reference spectrum with a corresponding film thickness;

FIG. 11 is a view showing an example of a process for polishing the wafer to be polished;

FIG. 12 is a view showing the wafer divided into pressing areas;

FIG. 13 is a view showing a notch detection device;

FIG. 14A is a view showing movement paths of a film thickness sensor across a surface of the wafer;

FIG. 14B is a view showing movement paths of the film thickness sensor across the surface of the wafer;

FIG. 15A is a view showing effects of a polishing process of this embodiment;

FIG. 15B is a view showing effects of the polishing process of this embodiment;

FIG. 16 is a view showing a pressure control flow in the pressure chamber by the operation controller;

FIG. 17 is a view for explaining the effect of the polishing process according to another embodiment; and

FIG. 18 is a view showing a flow of correcting the film thickness value by the operation controller.

### DESCRIPTION OF EMBODIMENTS

Embodiments of the present invention will be described in detail below with reference to the drawings.

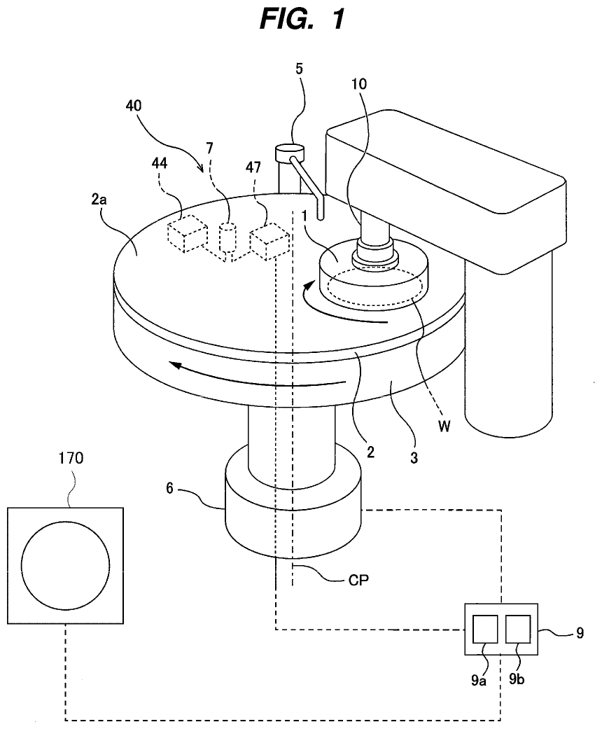

FIG. 1 is a schematic view showing one embodiment of a polishing apparatus. As shown in FIG. 1, the polishing apparatus includes a polishing table 3 that supports a polishing pad 2, a polishing head 1 that presses a wafer W (substrate, etc.) having a film onto the polishing pad 2, a table motor 6 that rotates the polishing table 3, a polishing liquid supply nozzle 5 for supplying a polishing liquid such as a slurry onto the polishing pad 2, and a film thickness sensor 40 (in this embodiment, an optical film thickness sensor 40) that measures the film thickness of the wafer W, and an operation controller 9 for controlling an operation of the polishing apparatus. An upper surface of the polishing pad 2 constitutes a polishing surface 2a for polishing the wafer W.

The polishing head 1 is coupled to a head shaft 10, and the head shaft 10 is connected to a polishing head motor (not shown) via a coupling mean such as a belt. The polishing head motor rotates the polishing head 1 together with the head shaft 10 in a direction shown by an arrow. The polishing table 3 is coupled to the table motor 6, and the table motor 6 is configured to rotate the polishing table 3 and the polishing pad 2 in the direction shown by the arrow.

The wafer W is polished as follows. While rotating the polishing table 3 and the polishing head 1 in the direction shown by the arrow in FIG. 1, a polishing liquid is supplied from the polishing liquid supply nozzle 5 onto the polishing surface 2a of the polishing pad 2 on the polishing table 3. The wafer W is rotated by the polishing head 1 around a head shaft 10, and the wafer W is pressed against the polishing surface 2a of the polishing pad 2 by the polishing head 1 while the polishing liquid is present on the polishing pad 2. The polishing table 3 rotates around its center CP. A surface of the wafer W is polished by a chemical action of the polishing liquid and a mechanical action of abrasive grains contained in the polishing liquid or the polishing pad 2.

The operation controller 9 is composed of at least one computer. The operation controller 9 includes a memory 9a that stores programs, and a processer 9b that executes operations according to instructions included in the programs. The processer 9b includes a CPU (central processing unit) or a GPU (graphic processing unit) that performs arithmetic operations according to instructions included in a program stored in the memory 9a. The memory 9a includes a main memory (e.g., random access memory) that can be accessed by the processer 9b, and an auxiliary memory (e.g., a hard disk drive or solid state drive) that stores data and programs.

The operation controller 9 is electrically connected to the film thickness sensor 40. In this embodiment, the film thickness sensor 40 guides light to the surface of the wafer W, detects reflected light from the wafer W, and outputs a signal corresponding to the film thickness of the wafer W to the operation controller 9. The operation controller 9 measures the film thickness of the wafer W based on the signal sent from the film thickness sensor 40 (more specifically, intensity measurement data of the reflected light from the wafer W).

In this embodiment, the film thickness sensor 40 is an optical film thickness sensor, but it may be any other film thickness sensor as long as the film thickness of the wafer W can be measured by the operation controller 9. In other words, the film thickness sensor 40 is a sensor that detects a physical quantity related to the film thickness of the wafer W. As an example, the film thickness sensor 40 may be an eddy current sensor. The eddy current sensor detects eddy currents corresponding to the film thickness of wafer W and outputs eddy current signals by its sensor coil passing a magnetic flux through a conductive film of the wafer W and generating the eddy currents. The operation controller 9 measures the film thickness of the wafer W based on this eddy current signal.

In this embodiment, the film thickness sensor 40 includes a light source 44 that emits light, a spectrometer 47, and an optical sensor head 7 coupled to the light source 44 and the spectrometer 47. The optical sensor head 7, the light source 44, and the spectroscope 47 are attached to the polishing table 3, and rotate together with the polishing table 3 and the polishing pad 2. A position of the optical sensor head 7 is a position that the optical sensor head 7 crosses the surface of the wafer W on the polishing pad 2 every time the polishing table 3 and the polishing pad 2 rotate once.

The memory 9a stores therein a program for generating a spectrum and detecting the film thickness of the wafer W, which will be described later. The light emitted from the light source 44 is transmitted to the optical sensor head 7, and guided from the optical sensor head 7 to the surface of the wafer W. The light is reflected by the surface of the wafer W, and the reflected light from the surface of the wafer W is received by the optical sensor head 7 and sent to the spectrometer 47. The spectrometer 47 separates the reflected light according to wavelength. In this manner, the film thickness sensor 40 detects an intensity of reflected light at each wavelength, and sends the intensity measurement data of the reflected light to the operation controller 9.

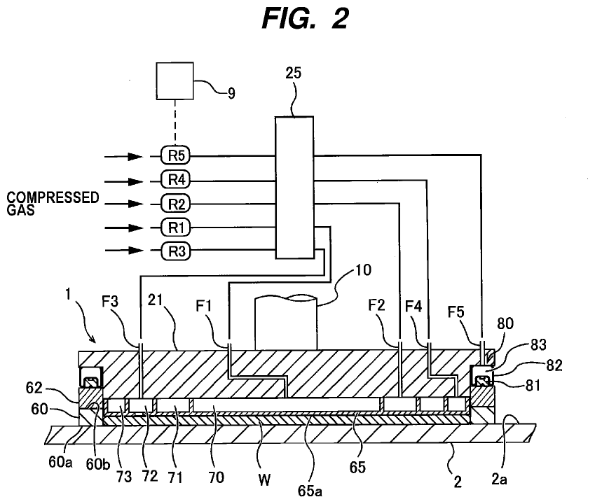

FIG. 2 is a cross sectional view of the polishing head. As shown in FIG. 2, the polishing head 1 includes an elastic membrane 65 for pressing the wafer W against the polishing surface 2a of the polishing pad 2, a head main body 21 holding the elastic membrane 65, an annular drive ring 62 arranged below the head main body 21, and an annular retaining ring 60 fixed to a lower surface of the drive ring 62.

The elastic membrane 65 is attached to a lower portion of the head main body 21. The head main body 21 is fixed to an end of the head shaft 10, and the head main body 21, the elastic membrane 65, the drive ring 62, and the retaining ring 60 are configured to rotate together as the head shaft 10 rotates. The retaining ring 60 and the drive ring 62 are configured to be movable up and down relative to the head main body 21. The head main body 21 is made of resin such as engineering plastic (e.g., PEEK).

The lower surface of the elastic membrane 65 constitutes a substrate pressing surface 65a that presses the wafer W against the polishing surface 2a of the polishing pad 2. The retaining ring 60 is arranged to surround the substrate pressing surface 65a, and the wafer W is surrounded by the retaining ring 60. Four pressure chambers 70, 71, 72, and 73 are provided between the elastic membrane 65 and the head main body 21.

The pressure chamber 70 is a circular central pressure chamber located at a center. The pressure chamber 73 is an annular edge pressure chamber located at an outermost periphery. Each of pressure chambers 71 and 72 is an intermediate pressure chamber located between pressure chambers 70 and 73.

The pressure chambers 70, 71, 72, 73 are formed by the elastic membrane 65 and the head main body 21. The central pressure chamber 70 has the circular shape, and the other pressure chambers 71, 72, and 73 have annular shape. These pressure chambers 70, 71, 72, and 73 are arranged (divided) concentrically. In this embodiment, the elastic membrane 65 forms four pressure chambers 70 to 73, but the number of pressure chambers described above is merely an example and may be changed as appropriate.

Gas transfer lines F1, F2, F3, and F4 are connected to the pressure chambers 70, 71, 72, and 73, respectively. One ends of the gas transfer lines F1, F2, F3, and F4 are connected to a compressed gas supply source (not shown) as a utility provided in a factory where the polishing apparatus is installed. A compressed gas such as compressed air is supplied to the pressure chambers 70, 71, 72, and 73 through the gas transfer lines F1, F2, F3, and F4, respectively. By supplying the compressed gas to the pressure chambers 70 to 73, the elastic membrane 65 expands, and the compressed gas in the pressure chambers 70 to 73 presses the wafer W against the polishing surface 2a of the polishing pad 2 via the elastic membrane 65. The pressure chambers 70 to 73 function as actuators for pressing the wafer W against the polishing surface 2a of the polishing pad 2.

The retaining ring 60 is an annular member arranged around the elastic membrane 65 and comes into contact with the polishing surface 2a of the polishing pad 2. The retaining ring 60 is arranged to surround the outermost periphery (peripheral portion) of the wafer W. The retaining ring 60 prevents the wafer W from flying out of the polishing head 1 during polishing the wafer W, and also adjusts an elastic behavior (rebound) of the polishing pad 2 to adjust the film thickness distribution of the outermost periphery of the wafer W.

An upper portion of the drive ring 62 is coupled to an annular retaining ring pressing device 80. The retaining ring pressing device 80 applies a downward load to an entire upper surface 60b of the retaining ring 60 via the drive ring 62, thereby pressing the lower surface 60a of the retaining ring 60 against the polishing surface 2a of the polishing pad 2.

The retaining ring pressing device 80 includes an annular piston 81 fixed to the upper portion of the drive ring 62, and an annular rolling diaphragm 82 connected to the upper surface of the piston 81. A retaining ring pressure chamber 83 is formed inside the rolling diaphragm 82. The retaining ring pressure chamber 83 is coupled to the compressed gas supply source via the gas transfer line F5. The compressed gas is supplied into the retaining ring pressure chamber 83 through the gas transfer line F5.

When the compressed gas is supplied from the compressed gas supply source to the retaining ring pressure chamber 83, the rolling diaphragm 82 pushes down the piston 81, the piston 81 pushes down the drive ring 62, and the drive ring 62 pushes the entire retaining ring 60 downward. In this manner, the retaining ring pressing device 80 presses the lower surface 60a of the retaining ring 60 against the polishing surface 2a of the polishing pad 2. The drive ring 62 is detachably coupled to the retaining ring pressing device 80. In one embodiment, the retaining ring pressing device 80 may have a structure that presses the lower surface 60a of the retaining ring 60 against the polishing surface 2a of the polishing pad 2 by applying a downward force of the polishing head 1 to the retaining ring 60.

The gas transfer lines F1, F2, F3, F4, and F5 extend via a rotary joint 25 attached to the head shaft 10. The polishing apparatus further includes pressure regulators R1, R2, R3, R4, and R5, and the pressure regulators R1, R2, R3, R4, and R5 are provided in the gas transfer lines F1, F2, F3, F4, and F5, respectively. The compressed gas from the compressed gas supply source is independently supplied into the pressure chambers 70 to 73 and the retaining ring pressure chamber 83 through the pressure regulators R1 to R5. The pressure regulators R1 to R5 are configured to adjust the pressure of the compressed gas in the pressure chambers 70 to 73 and the retaining ring pressure chamber 83. The pressure regulators R1 to R5 are connected to the operation controller 9.

The pressure regulators R1 to R5 are capable of changing internal pressures of the pressure chambers 70 to 73 and the retaining ring pressure chamber 83 independently of each other. The pressing force of the wafer W against the polishing surface 2a in the four regions corresponding to the wafer W, that is, a center portion, an inner middle portion, an outer middle portion, and an edge portion, and the pressing force of the retaining ring 60 on the polishing pad 2 can be adjusted independently. The gas transfer lines F1, F2, F3, F4, and F5 are also connected to atmosphere release valves (not shown), and it is also possible to release the pressure chambers 70 to 73 and the retaining ring pressure chamber 83 to the atmosphere. In this embodiment, the elastic membrane 65 forms four pressure chambers 70 to 73. In one embodiment, the elastic membrane 65 may form fewer than four pressure chambers or more than four pressure chambers.

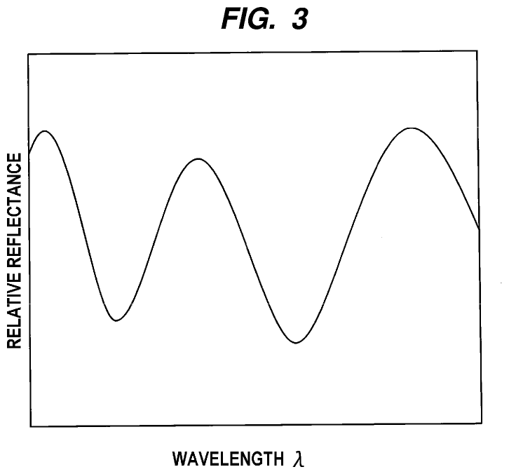

FIG. 3 is a view showing an example of a spectrum generated by the operation controller. In FIG. 3, a horizontal axis represents a wavelength of light reflected from the wafer, and a vertical axis represents a relative reflectance derived from the intensity of reflected light. The relative reflectance is an index value indicating the intensity of reflected light, and is a ratio between the intensity of light and a predetermined reference intensity. By dividing the intensity of light (actually measured intensity) at each wavelength by the predetermined reference intensity, unnecessary noise such as variations in intensity inherent in an optical system of the apparatus or the light source can be removed from the measured intensity.

The reference intensity is the intensity of light measured in advance for each wavelength, and the relative reflectance is calculated for each wavelength. Specifically, the relative reflectance is determined by dividing the intensity of light (actually measured intensity) at each wavelength by the corresponding reference intensity.

The operation controller 9 is configured to generate the spectrum of reflected light from the intensity measurement data of the reflected light. The spectrum of reflected light is expressed as a line graph (i.e., a spectral waveform) showing the relationship between the wavelength and intensity of reflected light. The intensity of reflected light can also be expressed as a relative value such as reflectance or relative reflectance.

In actual polishing, a dark level (background intensity obtained under conditions where light is blocked) is subtracted from the measured intensity to obtain a corrected measured intensity, the above dark level is subtracted from the reference intensity to obtain a corrected reference intensity. The relative reflectance is determined by dividing the corrected measured intensity by the corrected reference intensity. Specifically, the relative reflectance R (λ) can be determined using the following equation (1).

$$\begin{matrix}( numeral 1 ) & \\ R ( λ ) = \frac{E ( λ ) - D ( λ )}{B ( λ ) - D ( λ )} & ( 1 )\end{matrix}$$

Where, λ is the wavelength of light reflected from the substrate, E (λ) is the intensity at wavelength λ, B (λ) is the reference intensity at wavelength λ, and D (λ) is the background intensity (dark level) at wavelength λ measured under light shielded conditions.

The operation controller 9 generates the spectrum as shown in FIG. 3 from the intensity measurement data of the reflected light. Furthermore, the operation controller 9 determines the film thickness of the wafer W from the spectrum of the reflected light. The spectrum of the reflected light changes according to the film thickness of the wafer W. Therefore, the operation controller 9 can determine the film thickness of the wafer W from the spectrum of the reflected light. In this specification, a spectrum generated from reflected light from the wafer W to be polished will be referred to as a measured spectrum.

The operation controller 9 is configured to determine the film thickness by comparing the measured spectrum (i.e., measurement data) with a plurality of reference spectra (i.e., reference data). The operation controller 9 determines the reference spectrum that is closest in shape to the measured spectrum by comparing the measured spectrum generated during polishing with a plurality of reference spectra, and obtains the film thickness associated with the determined reference spectrum. The reference spectrum that is closest in shape to the measured spectrum is a spectrum that has a smallest difference in a relative reflectance between the reference spectrum and the measured spectrum.

The reference spectra are obtained in advance by polishing a reference wafer having the same or equivalent initial film thickness as the wafer to be polished (the wafer W corresponds to the wafer to be polished in this specification). The wafer to be polished is a wafer different from the reference wafer, and is a wafer on which a film thickness flattening process is performed. The reference wafer is a wafer on which a process of associating the reference spectrum with a corresponding film thickness is performed.

Each reference spectrum can be associated with the film thickness at which the reference spectrum is obtained. That is, each reference spectrum is obtained at a different film thickness, and the reference spectra correspond to a plurality of different film thicknesses. Therefore, by determining the reference spectrum whose shape is closest to the measured spectrum, the current film thickness can be estimated.

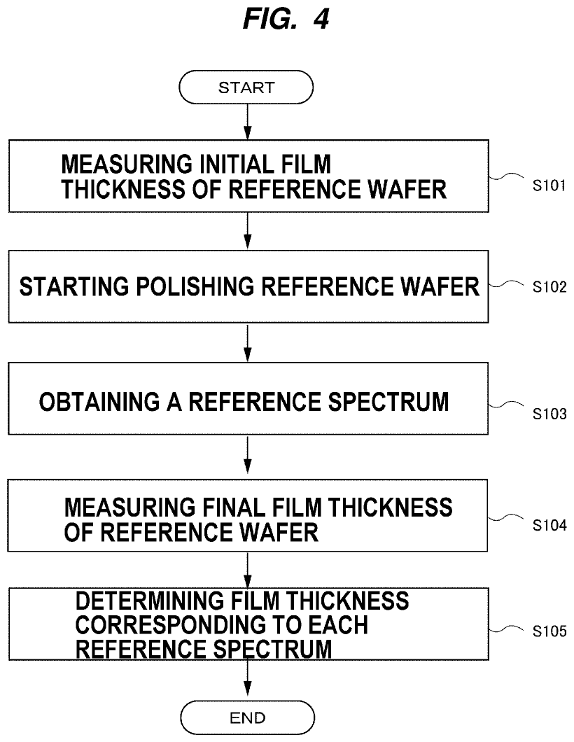

FIG. 4 is a view showing an example of processes of obtaining a plurality of reference spectra. First, a reference wafer having the same or equivalent film thickness as the wafer W is prepared. The reference wafer is transferred to a film thickness measuring device 170 (see FIG. 1), and an initial film thickness of the reference wafer is measured by the film thickness measuring device 170 (see step S101). The film thickness measuring device 170 is electrically connected to the operation controller 9.

Next, the reference wafer is polished while the slurry as the polishing liquid is supplied to the polishing pad 1 (see step S102). During polishing the reference wafer, a surface of the reference wafer is irradiated with light, and the spectrum (i.e., reference spectrum) of the reflected light from the reference wafer is obtained (see step S103).

The reference spectrum is obtained every time the polishing table 3 rotates once. Therefore, the reference spectra are obtained during polishing the reference wafer. After the polishing of the reference wafer is completed, the reference wafer is again transferred to the film thickness measuring device 170, and the film thickness (i.e., final film thickness) of the polished reference wafer is measured (see step S104).

If the polishing rate of the reference wafer is constant, the film thickness decreases linearly with a polishing time. The polishing rate can be calculated by dividing a difference between the initial film thickness and the final film thickness by the polishing time required to reach the final film thickness. As described above, the reference spectrum is periodically obtained each time the polishing table 3 rotates once, so the polishing time when each reference spectrum is obtained can be calculated from the rotational speed of the polishing table 3. In this manner, the operation controller 9 determines the film thickness corresponding to each reference spectrum (see step S105).

Each reference spectrum can be associated with a corresponding film thickness. Therefore, the operation controller 9 determines the reference spectrum whose shape is closest to the measured spectrum during polishing the wafer W, and determines the current film thickness of the wafer W from the film thickness associated with the reference spectrum.

The processes of polishing the wafer W to be polished will be described below. First, it is necessary to determine a first polishing condition (in other words, final target film thickness flat condition) in which a uniformity of the film thickness of the wafer W to be polished falls within a predetermined allowable range.

The first polishing condition may be a polishing condition (controlling the respective pressures of the pressure chambers 70, 71, 72, 73, and 83) determined in advance so that the final target film thickness is flat. The operation controller 9 is configured to polish the wafer W while controlling the pressure in each of the pressure chambers 70, 71, 72, 73, and 83 based on the first polishing condition.

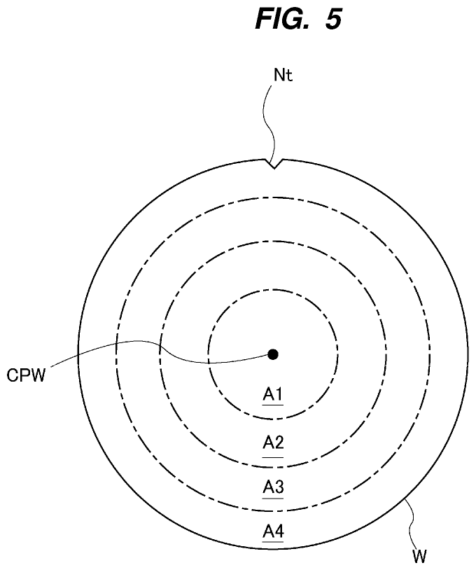

FIG. 5 is a view showing a plurality of pressing areas of a wafer divided corresponding to a plurality of pressure chambers. As shown in FIG. 5, the operation controller 9 divides the wafer W into a plurality of pressing areas A1 to A4 corresponding to the pressure chambers 70, 71, 72, and 73. These pressing areas A1 to A4 are arranged concentrically with a center CPW of the wafer W. A notch Nt is formed at an outer edge of the wafer W.

In one embodiment, the first polishing condition may be a polishing condition (CLC: closed loop control) in which the pressure of each pressure chamber 70 to 73 is feedback controlled in real time so that the film thickness (average film thickness) of each areas A1 to A4 of the wafer W is the average film thickness of the entire wafer W based on the film thickness measured by the film thickness sensor 40 during polishing of the wafer W. More specifically, the operation controller 9 calculates an average film thickness value in each of the pressing areas A1 to A4 based on the film thickness of the wafer W measured based on the signal output from the film thickness sensor 40. Thereafter, the operation controller 9 controls each of the pressure regulators R1 to R4 so that the difference between the average film thickness value of each of the pressing areas A1 to A4 and the average film thickness value of the entire wafer W is reduced, to control the pressures in the pressure chambers 70 to 73 corresponding to the pressing areas A1 to A4.

The operation controller 9 may control the pressure in the retaining ring pressure chamber 83 by controlling the pressure regulator R5 based on a method similar to the method described above.

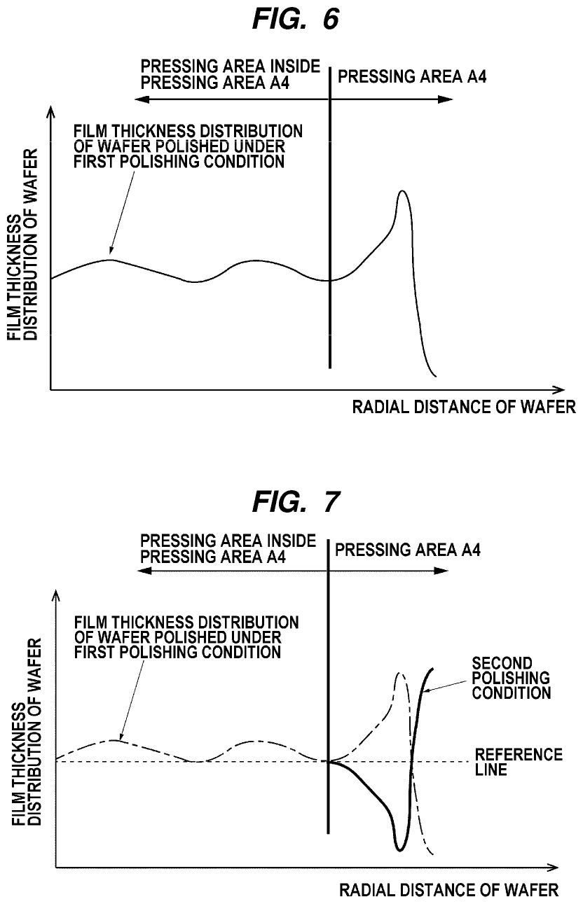

FIG. 6 is a view showing a polishing profile of the wafer when the wafer is polished under the first polishing condition. In FIG. 6, a horizontal axis represents the radial distance of the wafer W, and a vertical axis represents the film thickness distribution of the wafer W. A thick line in FIG. 6 indicates a boundary line between the pressing area A4 located at the outermost periphery of the wafer W and corresponding to the pressure chamber 73, and a pressing area inside the pressing area A4. In the embodiment shown in FIG. 6, the film thickness distribution in the radial direction of the after polishing wafer W when the wafer W is polished for a predetermined time will be described as the polishing profile of the wafer W. The polishing profile of the wafer W may include the polishing rate distribution in the radial direction of wafer W.

When the wafer W is polished under the first polishing condition, the uniformity of the film thickness of the wafer W falls within a predetermined allowable range in other areas (i.e., area excluding the outermost periphery) including the center portion of the wafer W. In the specific area including the outermost periphery of the wafer W, the residual film (film thickness after polishing) of the wafer W may vary greatly in the radial direction. That is, within the specific area including the outermost periphery of the wafer W, the difference in the film thickness between a portion with a large film thickness and a portion with a small film thickness is large. The outermost periphery of the wafer W tends to have a steep and asymmetric polishing profile due to the effect of rebound of the polishing pad 2, etc. It is difficult to obtain a flat film thickness distribution simply by adjusting the pressure of the pressure chamber in the specific area including the outermost periphery of the wafer W. The variations (so called residual film range) in the film thickness after polishing within the specific area including the outermost periphery of the wafer W tend to increase as the polishing time under the first polishing condition increases.

Therefore, in the embodiment, the operation controller 9 is configured to polish the wafer W based on the second polishing condition that reduces the variations in the film thickness in the radial direction of the wafer W in the outermost periphery of the wafer W. In the embodiment shown below, as an example of the specific area of the wafer W, an embodiment will be described in which the variations in the film thickness of the wafer W at the outermost periphery of the wafer W are reduced. The specific area of the wafer W is not limited to the outermost periphery of the wafer W. The variations in the film thickness of the wafer W may also occur in other areas other than the outermost periphery of the wafer W.

FIG. 7 is a view showing the second polishing condition. In FIG. 7, a horizontal axis represents the radial distance of the wafer W, and a vertical axis represents the film thickness distribution of the wafer W. In the embodiment shown in FIG. 7, the film thickness distribution in the radial direction of the after polishing wafer W when the wafer W is polished for a predetermined time will be described as the polishing profile of the wafer W. The polishing profile of the wafer W may include the polishing rate distribution in the radial direction of the wafer W.

The operation controller 9 polishes the wafer having the same or equivalent initial film thickness as the wafer W to be polished, based on the first polishing condition. Thereafter, the operation controller 9 determines the second polishing condition based on the first polishing profile (film thickness distribution or polishing rate distribution of the wafer W after polishing) obtained by polishing under the first polishing condition. The second polishing condition is a polishing condition that is a predetermined (adjusted) so that the second polishing profile having a distribution opposite to that of the first polishing profile (more specifically, the distribution of the pressing area on wafer W corresponding to the specific pressure chamber) is formed.

In other words, the second polishing condition is a polishing condition such that a thickest portion of the outermost periphery of the wafer W after polishing under the first polishing condition is more aggressively polished and a thinnest portion of the outermost periphery of the wafer W after polishing is suppressed. The second polishing profile has a distribution in which a sign of the numerical value indicating the film thickness of the wafer W or the polishing rate is reversed with respect to the distribution of the first polishing profile. A curve showing the distribution of the second polishing profile and a curve showing the distribution of the first polishing profile are line symmetrical to each other.

In the embodiment shown in FIG. 7, in the film thickness distribution on the coordinate system specified from the radial distance of the wafer W and the film thickness of the wafer W corresponding to the distance, a curve (curve showing the distribution of the second polishing profile) showing the film thickness distribution at the outermost periphery of the wafer W is line symmetrical about the reference line with respect to the curve showing the film thickness distribution at the outermost periphery of the wafer W polished under the first polishing condition (see the dashed-dotted line in FIG. 7). In the embodiment shown in FIG. 7, the curve showing the distribution of the second polishing profile is drawn as an ideal curve.

The second polishing condition is determined by polishing the wafer having the same or equivalent initial film thickness as the wafer W to be polished. First, the wafer W is polished in advance under the first polishing condition, and the first polishing profile is confirmed. Thereafter, another wafer is polished, and the second polishing condition is experimentally determined so that the polishing profile after polishing has a distribution opposite to that of the first polishing profile. Alternatively, in one embodiment, first, the wafer W is polished under the first polishing condition, and then the wafer W is polished while changing the polishing condition from the first polishing condition. The second polishing condition, which is switching a condition from the first polishing condition, is determined experimentally so that the polishing profile after polishing has a flat distribution. In one embodiment, the second polishing condition may be optimally selected from a database consisting of polishing conditions and polishing profiles stored in advance in the memory 9a, and/or may be determined by a polishing simulation.

The operation controller 9 stores the second polishing condition in the memory 9a, and is configured to polish the wafer W based on the second polishing condition. More specifically, the operation controller 9 controls the pressure of the specific pressure chamber among the pressure chambers 70, 71, 72, 73, and 83 at a predetermined fixed value based on the second polishing condition to polish the wafer W. The second polishing condition include a polishing condition for polishing the wafer W while controlling the pressure in the specific pressure chamber at a predetermined fixed value based on the second polishing profile.

In this embodiment, the specific pressure chamber includes an edge pressure chamber 73 that presses the outermost periphery of the wafer W, and an adjacent pressure chamber adjacent to the edge pressure chamber 73. The adjacent pressure chamber includes at least one pressure chamber of the intermediate pressure chamber 72 and the retaining ring pressure chamber 83. In this embodiment, the adjacent pressure chambers are both the intermediate pressure chamber 72 and the retaining ring pressure chamber 83. In one embodiment, the specific pressure chamber may be only the edge pressure chamber 73.

The second polishing conditions include polishing conditions determined by adjusting the pressure in a specific pressure chamber. In one embodiment, the second polishing conditions may include polishing conditions determined by adjusting the pressure of a pressure chamber other than a specific pressure chamber. For example, when the specific pressure chamber is the edge pressure chamber 73, the second polishing conditions include polishing conditions determined by adjusting the pressure of an adjacent pressure chamber adjacent to the edge pressure chamber 73.

In one embodiment, the second polishing condition may include a polishing condition determined by adjusting the pressing force of the retaining ring 60 arranged so as to surround the outermost periphery of the wafer W against the polishing surface 2a. In this case, the operation controller 9 controls the retaining ring pressing device 80 that applies the downward force of the polishing head 1 to the retaining ring 60 based on the second polishing condition.

In this embodiment, the operation controller 9 controls the pressure of each of the edge pressure chamber 73 and the adjacent pressure chambers 72 and 83 based on the second polishing condition to feedback control the pressure of each of the other pressure chambers 70 and 71 excluding the edge pressure chamber 73 and the adjacent pressure chambers 72 and 83 based on the first polishing condition.

The first polishing condition is a polishing condition in which the pressure of each of the pressure chambers 70 and 71 is feedback controlled so that the difference between the average film thickness value of the area corresponding to each of the other pressure chambers 70 and 71 and the average film thickness value of the entire wafer W is reduced based on the signals output from the film thickness sensor 40 during polishing.

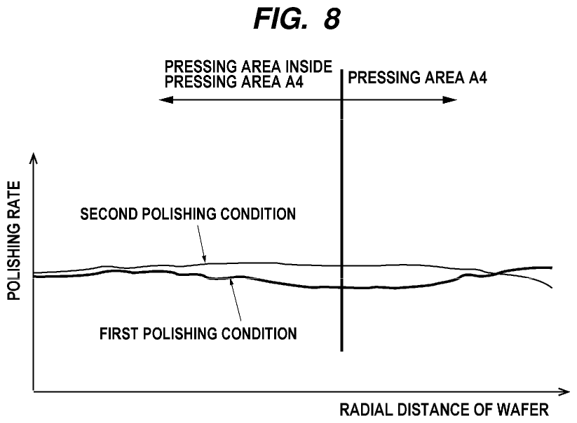

FIG. 8 is a view showing a polishing rate of the wafer polished under the first polishing condition and the second polishing condition. In FIG. 8, a horizontal axis represents the radial distance of the wafer W, and a vertical axis represents the polishing rate of the wafer W. FIG. 8 shows an enlarged view of the polishing rate of the outer portion of the wafer W. As shown in FIG. 8, the polishing rate in the pressing area A4 on the wafer W under the first polishing condition and the polishing rate in the pressing area A4 on the wafer W under the second polishing condition are reversed. Therefore, the operation controller 9 can improve the uniformity of the film thickness at the outermost periphery of the wafer W by polishing the wafer W using a combination of the first polishing condition and the second polishing condition.

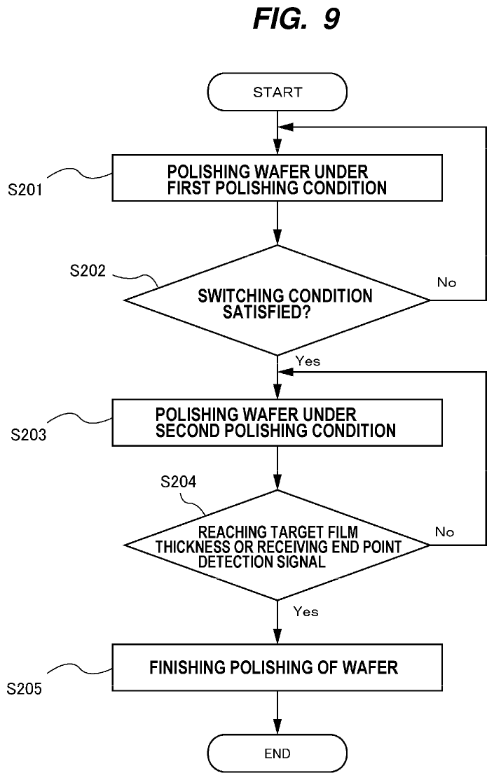

FIG. 9 is a view showing an example of processes of polishing the wafer to be polished. As shown in step S201 in FIG. 9, the operation controller 9 polishes the wafer W under the first polishing condition (first polishing process). After that, the operation controller 9 determines whether a predetermined switching condition is satisfied (see step S202), and if the switching condition is not satisfied (see “No” in step S202), the operation controller 9 continues step S201. If the switching conditions are satisfied (see “Yes” in step S202), the operation controller 9 switches the polishing condition from the first polishing condition to the second polishing condition (see step S203), and polishes the wafer W under the second polishing condition (second polishing process).

When the variation (more specifically, the difference between the maximum film thickness and the minimum film thickness) in the residual film thickness at the outermost periphery (i.e., specific region) of the wafer W is too large, even if the polishing condition is switched from the first polishing condition to the second polishing condition, the variation in the film thickness at the outermost periphery of the wafer W may not be eliminated. Therefore, as the above switching condition, the operation controller 9 may switch (first switching condition) the polishing condition from the first polishing condition to the second polishing condition when the difference (so called residual film range) between the maximum film thickness and the minimum film thickness of the outermost periphery of the wafer W during polishing of the wafer W under the first polishing condition becomes larger than a predetermined threshold value.

If the variation of the film thickness within the specific area of wafer W corresponding to the specific pressure chamber is large, the variation of the film thickness may not be eliminated by adjusting the pressure of the specific pressure chamber. Therefore, in the embodiment described above, the operation controller 9 switches the polishing condition from the first polishing condition to the second polishing condition when the residual film range of the wafer W under the first polishing condition becomes larger than a predetermined threshold value.

If the polishing condition is switched from the first polishing condition to the second polishing condition when the remaining polishing time is too short, the variation of the film thickness in the specific area of the wafer W may not be resolved. Therefore, the operation controller 9 may switch (second switching condition) the polishing condition from the first polishing condition to the second polishing condition based on the time required to resolve the difference between the maximum value and the minimum value of the film thickness of the outermost periphery of the wafer W by polishing under the second polishing condition and the remaining polishing time to the final target film thickness as the above switching condition.

The polishing rate in the case of polishing the wafer W under the second polishing condition is known in advance by the process of determining the second polishing condition. Therefore, the operation controller 9 can calculate the time required to reduce (eliminate) the residual film range of the wafer W during polishing of the wafer W under the first polishing condition when the wafer W is polished under the second polishing condition. Therefore, in one embodiment, the operation controller 9 may switch the polishing condition from the first polishing condition to the second polishing condition when the required polishing time under the second polishing condition reaches or approaches the predetermined remaining time. The predetermined remaining time is, for example, the same as the time required for the film thickness of the wafer W to reach the final target film thickness when the wafer W is polished under the second polishing condition after the switching timing.

While polishing the wafer W under the first polishing condition, the operation controller 9 calculates the time required to reduce the residual film range of the wafer W under the second polishing condition (i.e., the above required polishing time) and the remaining polishing time (i.e., the above remaining time). The remaining polishing time is calculated based on the following formula. The remaining polishing time=(the current film thickness of the wafer W−the target film thickness of the wafer W)/assumed polishing rate under the second polishing condition.

If the required polishing time is smaller than the remaining time (the required polishing time<<the remaining time), the polishing time under the second polishing condition becomes longer and the remaining film profile of the wafer W becomes worse. When the required polishing time and the remaining time are the same (the required polishing time=the remaining time), the remaining film range of the wafer W is eliminated and the film thickness of the wafer W reaches the target film thickness (ideal condition). If the required polishing time is greater than the remaining time (the required polishing time>the remaining time), the film thickness of the wafer W reaches the target film thickness before the remaining film range is resolved, and the remaining film range is not fully resolved. If the polishing continues in this state, an overpolishing will occur. Therefore, the operation controller 9 should switch the polishing condition from the first polishing condition to the second polishing condition when the required polishing time and the remaining time are the same.

According to the second switching condition, when there is a difference in the total polishing amount, the remaining film range that can be allowed by polishing using the first polishing condition can be changed. Therefore, for example, when there is a difference in the initial film thickness of the wafer W, it can be optimized accordingly. The “time required to reach the final target film thickness” means, in the case of polishing to remove the film on the wafer W, the final target film thickness is zero, i.e., the time required to clear the excess film.

In one embodiment, the operation controller 9 may switch the polishing condition from the first polishing condition to the second polishing condition based on the first switching condition and the second switching condition. In one embodiment, the operation controller 9 may switch the polishing condition from the first polishing condition to the second polishing condition when the average film thickness of the entire wafer W reaches a predetermined film thickness. In one embodiment, the operation controller 9 may switch the polishing condition from the first polishing condition to the second polishing condition when the polishing time of the wafer W reaches the predetermined polishing time.

After performing step S203 in FIG. 9, the operation controller 9 terminates polishing of the wafer W (see step S205) by receiving an endpoint detection signal from the film thickness sensor 40 indicating that the average film thickness of the entire wafer W has reached the target film thickness or that a material formed on the wafer W has reached the interface with a different material (see “Yes” in step S204). If the end point detection signal is not received (see “No” in step S204), the operation controller 9 continues polishing the wafer W under the second polishing condition. The operation controller 9 may continue polishing the wafer W under the second polishing condition if the residual film range in the specific area is not less than a predetermined value when the end point detection signal is received. The operation controller 9 may also issue an alarm if the residual film range within the specific area is not less than a predetermined value when the end point detection signal is received.

In the embodiment described above, the polishing head 1 has the pressure chambers (airbags), but pressure elements for pressing the wafer W are not limited to this embodiment. Technical concepts of the present embodiment are applicable when the pressure elements are arranged in the radial direction of the wafer W to apply the same pressure to the wafer W. The pressure elements include, for example, piezoelectric elements.

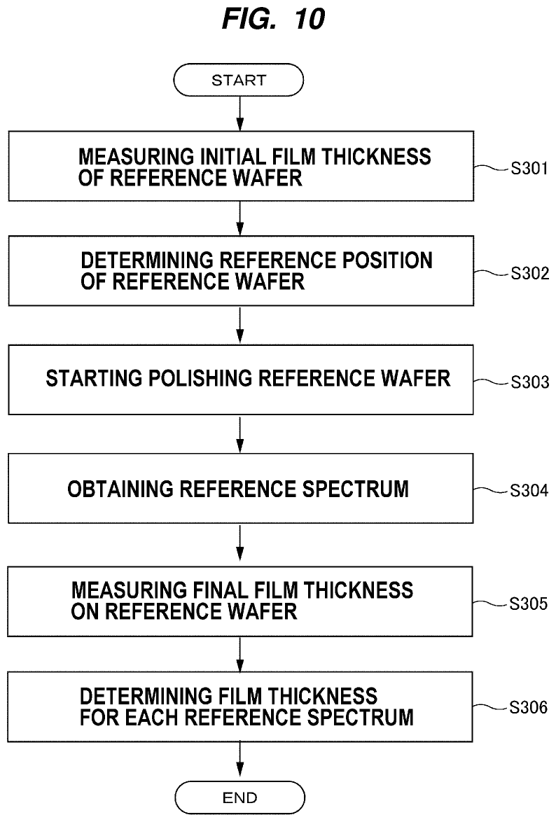

FIG. 10 is a view showing an example of the process of associating the reference spectrum with the corresponding film thickness. First, a reference wafer having the same or equivalent film thickness as the wafer W is prepared. The reference wafer is transported to the film thickness measuring device 170 (see FIG. 1), and the initial film thickness of the reference wafer is measured by the film thickness measuring device 170 (see step S301). The film thickness measuring device 170 is electrically connected to the operation controller 9. Based on the film thickness (distribution) of the reference wafer measured by the film thickness measuring device 170, the operation controller 9 determines a reference position for obtaining the reference spectrum over a wide film thickness range (see step S302).

In this manner, the operation controller 9 obtains information from the film thickness measuring device 170 related to a specific location that is a part of the circumference of the reference wafer. The film thickness measuring device 170 may be arranged inside the polishing apparatus. In this case, the film thickness measuring device 170 constitutes a part of the components of the polishing apparatus. In one embodiment, the film thickness measuring device 170 may be arranged outside the polishing apparatus.

The reference wafer is polished to obtain the reference spectra corresponding to various film thicknesses. Based on the measured film thickness of the reference wafer, the operation controller 9 determines the maximum film thickness position (i.e., where the reference wafer is thicker) where the maximum film thickness value is obtained and the minimum film thickness position (i.e., where the reference wafer is thinner) where the minimum film thickness value is obtained, and determines one of the maximum film thickness position and the minimum film thickness position as the reference position. In one embodiment, the operation controller 9 may determine both the maximum film thickness position and the minimum film thickness position as the reference position.

In one embodiment, the operation controller 9 may determine the maximum film thickness value and the minimum film thickness value, based on the measured film thickness of the reference wafer, calculate the difference between the average film thickness value of the entire reference wafer and the maximum film thickness value, and the difference between the average film thickness value of the entire reference wafer and the minimum film thickness value, and determine the position on the reference wafer where the film thickness value with the largest difference is obtained as the reference position.

Next, the reference wafer is polished while the slurry as the polishing liquid is supplied onto the polishing pad 1 (see step S303). During polishing of the reference wafer, light is irradiated onto the surface of the reference wafer and the spectrum of reflected light from the reference wafer (i.e., reference spectrum) is obtained (see step S304).

The operation controller 9 obtains the reference spectrum at each measurement point on the reference wafer each time the polishing table 3 makes one rotation. The operation controller 9 controls at least one of the rotational speed of the polishing head 1 and the rotational speed of the polishing table 3 so that the film thickness sensor 40 crosses the reference position on the reference wafer during polishing. With such control, the film thickness sensor 40 detects the reflected light at the reference position, and the operation controller 9 obtains the reference spectrum including the reference position.

By obtaining the reference spectrum including the reference position, the operation controller 9 can obtain the reference spectra over a wide range of film thickness values. Therefore, the operation controller 9 can more reliably determine the reference spectrum that is closest in shape to the measurement spectrum generated during polishing, and as a result, can measure (obtain) the film thickness of the wafer W having any film thickness.

The reference spectrum is obtained each time the polishing table 3 makes one rotation. Therefore, the reference spectra are obtained during polishing of the reference wafer. After polishing of the reference wafer is completed, the reference wafer is transported again to the film thickness measuring device 170, where the film thickness (i.e., final film thickness) of the polished reference wafer is measured (see step S305).

If the polishing rate of the reference wafer is constant, the film thickness decreases linearly with the polishing time. The polishing rate can be calculated by dividing the difference between the initial film thickness and the final film thickness by the polishing time taken to reach the final film thickness. Since the reference spectrum is periodically obtained each time the polishing table 3 rotates as described above, the polishing time when each reference spectrum is obtained can be calculated from the rotational speed of the polishing table 3. In this manner, the operation controller 9 determines the film thickness corresponding to each reference spectrum (see step S306).

Each reference spectrum can be associated (tied together) to a corresponding film thickness. Therefore, the operation controller 9 can determine the current film thickness of the wafer W from the film thickness associated with the reference spectrum by determining the reference spectrum whose shape is closest to the measurement spectrum during polishing of the wafer W.

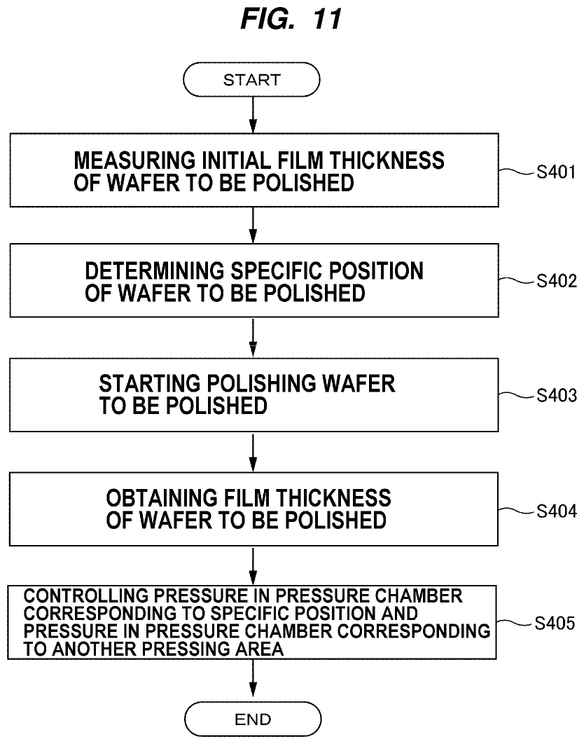

FIG. 11 is a view showing an example of a process for polishing the wafer to be polished. In order to improve the uniformity of the film thickness of the wafer W to be polished, it is necessary to determine the specific position, which is a part of the circumference of the wafer W. Therefore, as shown in step S401 of FIG. 11, the wafer W is transported to the film thickness measuring device 170, and the initial film thickness of the wafer W is measured by the film thickness measuring device 170.

Therefore, similar to step S302 in FIG. 10, the operation controller 9 determines the specific position of the wafer W based on the film thickness of the wafer W measured by the film thickness measuring device 170 (see step S402).

A method of determining the specific position is the same as the method of determining the reference position. Based on the film thickness of the wafer W measured before polishing, the operation controller 9 determines the maximum film thickness position (i.e., where the film thickness of wafer W is thick) where the maximum film thickness value is obtained and the minimum film thickness position (i.e., where the film thickness of wafer W is thin) where the minimum film thickness value is obtained, and determines at least one of the maximum film thickness position and the minimum film thickness position as the specified position.

In one embodiment, the operation controller 9 may determine the maximum film thickness value and the minimum film thickness value based on the measured film thickness of the wafer W measured before polishing, calculate the difference between the average film thickness value of the entire wafer W and the maximum film thickness value, and the difference between the average film thickness value of the entire wafer W and the minimum film thickness value, and determine the position on the wafer W where the thickness value with the largest difference is obtained as the specific position.

The operation controller 9 obtains the film thickness distribution information of the wafer W measured by the film thickness measuring device 170, and determines the specific position of the wafer W. As an embodiment, if the film thickness measuring device 170 is arranged outside of the polishing apparatus, the operation controller 9 may obtain only the position information of the specific position determined from the film thickness distribution of the wafer W.

After determining the specific position of the wafer W, the operation controller 9 starts polishing the wafer W (see step S403). During this polishing, light is irradiated on the surface of the wafer W, and the operation controller 9 obtains the spectrum of reflected light from the wafer W (i.e., a measurement spectrum). The operation controller 9 determines the reference spectrum whose shape is closest to the obtained measurement spectrum and obtains the film thickness associated with the determined reference spectrum (see step S404).

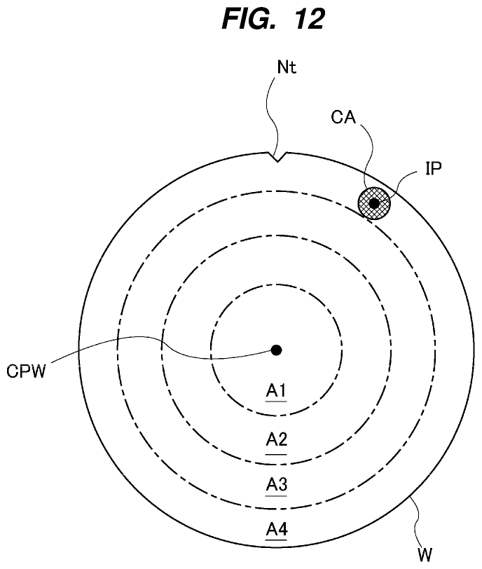

The operation controller 9 controls the pressure regulators R1, R2, R3, and R4 to adjust the pressing force on the polishing surface 2a of the wafer W based on the film thickness of the wafer W. In this embodiment, the operation controller 9 divides the area on the wafer W into the pressing areas A1, A2, A3, and A4 corresponding to the pressure chambers 70, 71, 72, and 73 (see FIG. 12).

FIG. 12 is a view showing the wafer divided into the pressing areas. In FIG. 12, the area on the wafer W is divided into the pressing area A1 corresponding to the pressing chamber 70, the pressing area A2 corresponding to the pressing chamber 71, the pressing area A3 corresponding to the pressing chamber 72, and the pressing area A4 corresponding to the pressing chamber 73. The pressing area A1 has a circular shape, and each of the pressing areas A2 to A4 has an annular shape. These pressing areas A1 to A4 are arranged concentrically with the center CPW of the wafer W. The operation controller 9 is configured to independently adjust the pressing force of the wafer W for each of the pressing areas.

As shown in FIG. 12, a specific position IP exists in the pressing area A4 of the wafer W. In the embodiment shown in FIG. 12, the specific position IP is a single point on the wafer W. However, the specific position IP may be a plurality of points in a narrow area on the wafer W or a plurality of points in a wide area on the wafer W. Therefore, the operation controller 9 determines a control target area CA that includes the specific position IP. If an area of a certain size including the specific position IP is used as the control target area, the adjustment of film thickness uniformity described below can be performed stably. In this embodiment, the control target area CA is determined within a range in the circumferential direction (i.e., a range belonging to any of the areas A1 to A4). In one embodiment, when the specific position IP is a point on the wafer W, the control target area CA may also be a point on the wafer W.

The operation controller 9 determines a control target film thickness value in the control target area CA, and calculates the average film thickness value of the entire wafer W based on the film thickness of the wafer W measured by the film thickness sensor 40. The control target film thickness value may correspond to the maximum film thickness value or the minimum film thickness value determined based on the film thickness of the wafer W measured by the film thickness sensor 40, or it may correspond both the maximum film thickness value and the minimum film thickness value. In one embodiment, the control target film thickness value may be the average value of the film thickness values in the control target area CA.

The operation controller 9 controls at least one of the rotational speed of the polishing head 1 and the rotational speed of the polishing table 3 so that the film thickness sensor 40 crosses the control target area CA on the wafer W. For this control, the operation controller 9 needs to determine the position of the control target area CA while polishing the wafer W.

As an example of a method of determining the position of the control target area CA, the operation controller 9 identifies the reference position (e.g., notch position Nt in FIG. 12) of a circumferential angle (i.e., wafer angle) of the wafer W while polishing the wafer W, and determines the position of the control target area CA as the wafer angle.

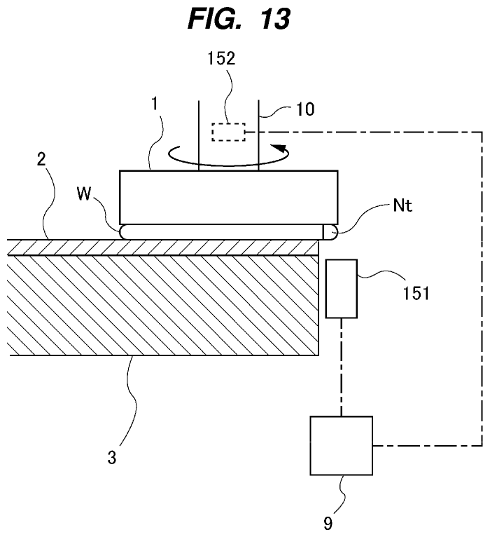

Assuming that the wafer W does not shift circumferentially with respect to the polishing head 1, a mounting angle of the wafer W to the polishing head 1 at the start of polishing is always kept constant, and by knowing the rotational angle of the polishing head 1 by a rotary encoder 152 (see FIG. 13), the operation controller 9 identifies the notch position Nt, and determines the position of the control target area CA. Even without specifying the position of the notch position Nt, it is possible to determine the position of the control target area CA from the rotational angle of the polishing head 1 because the positional relationship between the notch position Nt and the control target area CA is determined in advance.

On the other hand, the wafer W may shift circumferentially with respect to the polishing head 1 due to a frictional force acting between the wafer W and the polishing pad 1. In this case, the relative angle between the notch position Nt and the polishing head 1 will also shift, so the operation controller 9 identifies the notch position Nt of the wafer W in real time during polishing of the wafer W, and determines the position of the control target area CA based on the notch position Nt.

FIG. 13 is a view showing a notch detection device. As shown in FIG. 13, the polishing apparatus may include a notch detection device 151 that detects the notch position Nt of the wafer W. The notch detection device 151 may include a sensor such as an eddy current sensor, an optical sensor, or an image sensor. In the embodiment shown in FIG. 13, the notch detection device 151 is arranged on a side of the polishing table 3. The polishing head 1 is moved to a position where the periphery (more specifically, the notch position Nt) of the wafer W held by the polishing head 1 protrudes from the polishing pad 2, and rotates the wafer W.

The notch detector 151 detects the notch position Nt of the wafer W rotating out of the polishing pad 2, and outputs the detection signal to the operation controller 9. The rotary encoder 152 detects signals corresponding to the rotational angle of the polishing head 1, and outputs detection signals to the operation controller 9. In this manner, the operation controller 9 can obtain the relationship between the notch position Nt and the rotational angle of the polishing head 1, and determine the relative angle between the notch position Nt and the polishing head 1 in real time. In one embodiment, the operation controller 9 may identify the notch position Nt based on the signal output from the film thickness sensor 40. In this case, the film thickness sensor 40 corresponds to a notch detection device.

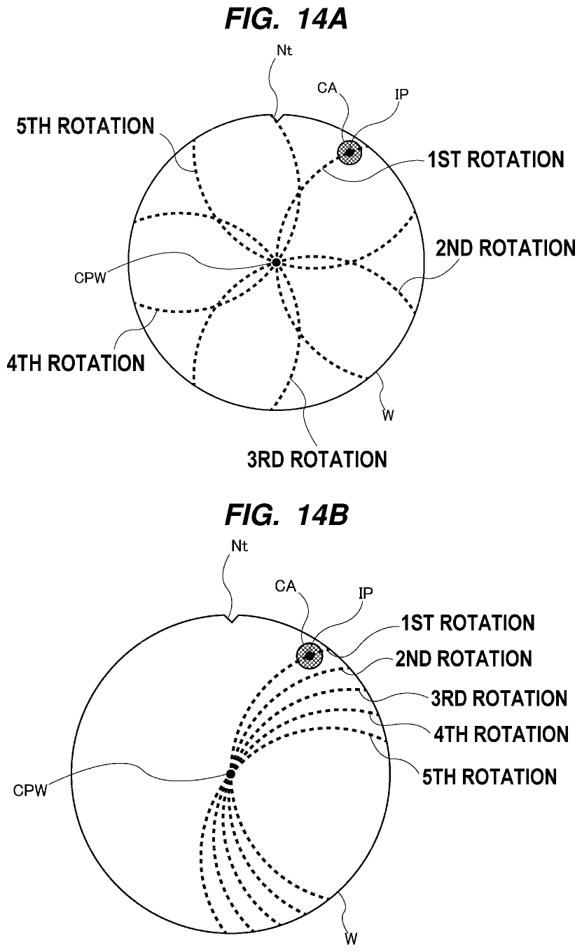

FIGS. 14A and 14B are views showing movement paths of the film thickness sensor across the surface of the wafer. In FIGS. 14A and 14B, the movement paths of the film thickness sensor 40 are shown by five dotted lines. In the embodiment shown in FIGS. 14A and 14B, the film thickness sensor 40 crosses the specific position IP during the first rotation of the polishing table 3.

As shown in FIGS. 14A and 14B, the operation controller 9 can control the movement path of the film thickness sensor 40 by controlling at least one of the rotational speed of the polishing head 1 and the rotational speed of the polishing table 3. Therefore, the operation controller 9 controls at least one of the rotational speed of the polishing head 1 and the rotational speed of the polishing table 3 based on the determined relative angle so that the film thickness sensor 40 crosses the specific position IP on the surface of the wafer W.

For example, the operation controller 9 can determine the movement path of the film thickness sensor 40 by determining a rotational speed ratio between the rotational speed of the polishing head 1 and the rotational speed of the polishing table 3. The rotational speed ratio in the embodiment shown in FIG. 14A and the rotational speed ratio in the embodiment shown in FIG. 14B are different from each other. Therefore, when the relative angle between the notch position Nt and the polishing head 1 is changed, the operation controller 9 determines the rotational speed ratio between the rotational speed of the polishing head 1 and the rotational speed of the polishing table 3 so that the film thickness sensor 40 crosses the specific position IP on the surface of the wafer W.

In this manner, the operation controller 9 measures the film thickness of the control target area CA including the specific position IP during polishing based on the signal output from the film thickness sensor 40, and controls the pressures in the pressure chambers 70 to 73 of the polishing head 1 corresponding to the control target area CA by controlling the pressure regulators R1 to R4 based on the measured film thickness.

More specifically, as shown in step S405 of FIG. 11, the operation controller 9 controls the pressure in the pressure chambers 70 to 73 of the polishing head 1 corresponding to the specific position IP (or control target area CA) so that the difference between the control target film thickness value and the average film thickness value of the entire wafer W is reduced. In the embodiment shown in FIG. 12, the control target area CA is arranged on the wafer W at a position corresponding to the pressing area A4, and the area A4 corresponds to the pressure chamber 73. Therefore, the operation controller 9 controls the pressure regulator R4 to control the pressure in the pressure chamber 73.

The operation controller 9 divides the pressing areas A1 to A4 on the wafer W divided corresponding to the pressure chambers 70 to 73 into a specific pressing area including the specific position IP and an other pressing area excluding the specific pressing area. In this embodiment, the specific pressing area corresponds to the pressing area A4, and the other pressing area correspond to pressing areas A1 to A3.

The operation controller 9 calculates the average film thickness value in each of the other pressing area A1 to A3 based on the film thickness of the wafer W measured by the film thickness sensor 40. The operation controller 9 then controls the pressure in the pressure chambers 70 to 72 corresponding to the other pressing area A1 to A3 by controlling each of the pressure regulators R1 to R3 so that the difference between the average film thickness value in each of the other pressing area A1 to A3 and the average film thickness value of the entire wafer W is reduced.

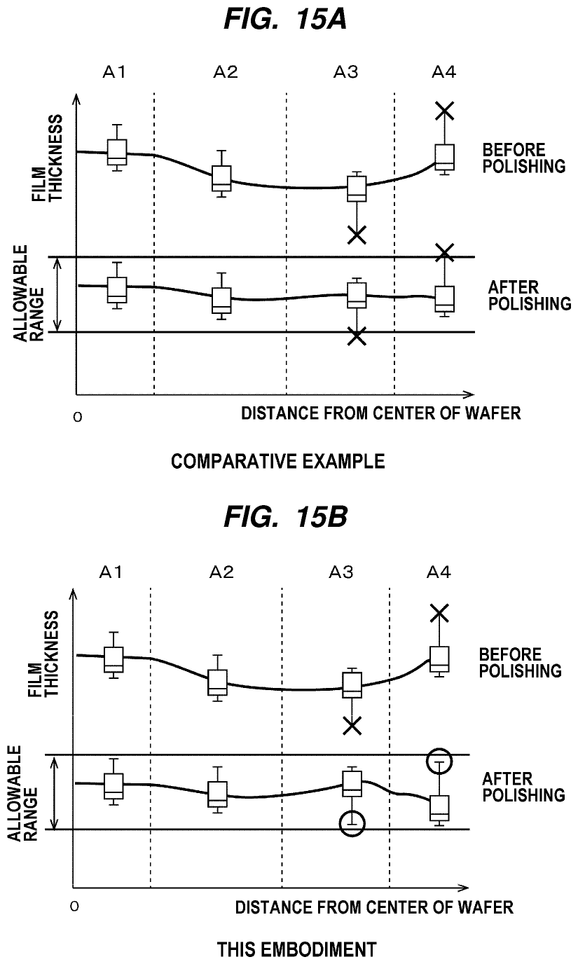

FIGS. 15A and 15B are views showing effects of the polishing process of this embodiment. In FIG. 15A, a profile of the average film thickness of the wafer W before and after polishing is shown by the polishing process as a comparative example, and in FIG. 15B, a profile of the average film thickness of the wafer W before and after polishing is shown by the polishing process according to the present embodiment. In each of FIGS. 15A and 15B, a horizontal axis represents the distance of the wafer W from the center CPW, and a vertical axis represents the film thickness of the wafer W. In FIGS. 15A and 15B, the film thickness of the wafer W is represented as a box-and-whisker view as the film thickness at each measurement point within the pressing areas A1 to A4.

As shown in FIG. 15A, in the film thickness of wafer W before polishing, the minimum film thickness value of the pressing area A3 is particularly smaller (or thinner) than the thicknesses of other pressing areas A1, A2, and A4. The maximum film thickness value of the pressing area A4 is particularly larger (or thicker) than the thicknesses of the other pressing areas A1, A2, and A3. In the polishing process as a comparative example, the operation controller 9 calculates the average film thickness values in each of the pressing areas A1 to A4 and the average film thickness value of the entire wafer W based on the signals detected by the film thickness sensor 40. Therefore, since operation controller 9 calculates the average film thickness value in each of pressing areas A3 and A4, the difference between the average film thickness value in each of pressing areas A1 and A2 and the average film thickness value in each of pressing areas A3 and A4 may be small.

Even in such a case, the operation controller 9 controls the pressure of each of the pressure chambers 70 to 73 to polish the wafer W so that the difference between the average film thickness value in each of the pressing areas A1 to A4 and the average film thickness value of the entire wafer W is reduced. Therefore, in the wafer W after polishing, the thickness of the film thickness in the entire wafer W may not fall within a predetermined (desired) allowable range.

According to this embodiment, the operation controller 9 controls the pressure in the specific pressing area individually at a different pressure from these of the other pressing areas. More specifically, the operation controller 9 controls the pressure in the pressure chambers 72 and 73 so that the difference between the control target film thickness value of each of the specific pressing areas A3 and A4 and the average film thickness value of the entire wafer W is reduced. The operation controller 9 controls the pressure in each of the pressure chambers 70 and 71 so that the difference between the average film thickness value of each of the other pressing areas A1 and A2 and the average film thickness value of the entire wafer W is reduced. As shown in FIG. 15B, the operation controller 9 may determine the specific pressing areas to control the pressure of the determined specific pressing areas individually.

In the embodiment shown in FIG. 15B, the pressure in the pressure chamber 72 is reduced compared to the pressure in the comparative example because the control target film thickness value in the pressing area A3 is smaller than the average film thickness value. As a result, the overall amount of polishing in the pressing area A3 is smaller than the amount of polishing in the comparative example. Since the control film thickness value in the pressing area A4 is larger than the average film thickness value, the pressure in the pressure chamber 73 is increased compared to the pressure in the comparative example. As a result, the amount of polishing in the pressing area A4 is larger than the amount of polishing in the comparative example. With this configuration, the polishing head 1 can keep the thickness of the film thickness in a thickest portion and the thickness of the film thickness in a thinnest portion of the entire wafer W within the desired allowable range (see FIG. 15B). As a result, the uniformity of the film thickness throughout the wafer W can be improved.

In the embodiment described above, the polishing head has the pressure chambers (air bags), but the technical concepts of the embodiment is applicable to any polishing head with concentrically arranged pressure elements. The pressing force exerted on the substrate by the concentrically arranged the pressing elements is controlled based on the control target film thickness value in the control target area including the specific position. The pressure elements include, for example, piezoelectric elements.

In the embodiment described above, the method of estimating film thickness by determining the reference spectrum that is closest in shape to the measurement spectrum is used, but other algorithms may be used to estimate film thickness.

In the embodiment described above, the operation controller 9 is configured to determine the specific position of the wafer W based on the film thickness of the wafer W measured by the film thickness measuring device 170, and to control the pressure in the pressure chamber of the polishing head 1 corresponding to the specific position. In one embodiment, the operation controller 9 may be configured to control the pressure in the pressure chamber of the polishing head 1 without measuring the film thickness of the wafer W in advance. The configuration of the operation controller 9 is described below with reference to the drawings.

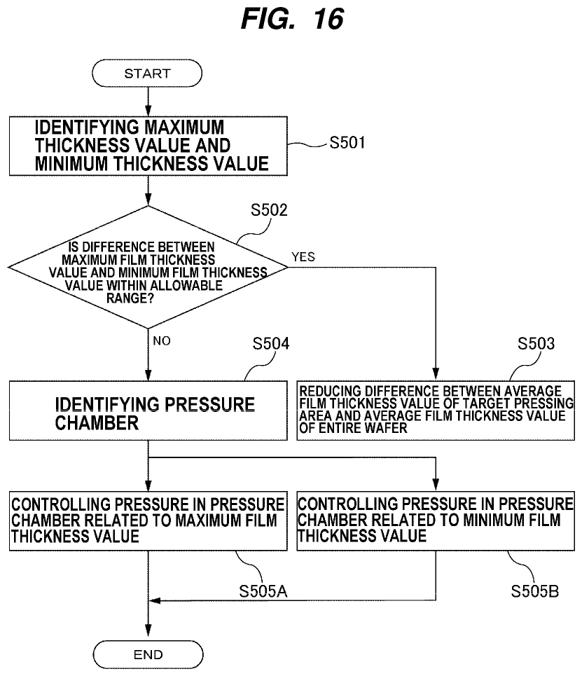

FIG. 16 is a view showing a pressure control flow in the pressure chamber by the operation controller. As shown in step S501 of FIG. 16, the operation controller 9 identifies the maximum film thickness value and the minimum film thickness value from the entire film thickness of the wafer W obtained during polishing of the wafer W by the film thickness sensor 40. More specifically, the operation controller 9 identifies the maximum film thickness value and the minimum film thickness value in the entire wafer W from the signals output from the film thickness sensor 40.

The operation controller 9 divides the area on the wafer W into the pressing areas A1, A2, A3, and A4 corresponding to the pressure chambers 70, 71, 72, and 73. In other words, the operation controller 9 classifies each measurement data obtained by the film thickness sensor 40 for each pressing area A1, A2, A3, and A4 based on the trajectory of the film thickness sensor 40 as it crosses the surface of the wafer W. The operation controller 9 identifies the maximum film thickness value and the minimum film thickness value as well as the average film thickness value for each of the pressing areas A1, A2, A3, and A4. The operation controller 9 also identifies the average film thickness value for the entire wafer W.

As shown in step S502 of FIG. 16, the operation controller 9 determines whether the difference (i.e., the film thickness range) between the maximum film thickness value and the minimum film thickness value in the entire wafer W is within the desired (predetermined) allowable range. If the film thickness range is within the allowable range (see “YES” in step S502), the operation controller 9 controls the pressure in each pressure chamber by controlling each of the pressure regulators so that the difference between the average film thickness value in each pressing area and the average film thickness value of the entire wafer W is reduced (see step S503).

If the film thickness range is outside the allowable range (see “NO” in step S502), the operation controller 9 identifies at least one of the pressure chamber corresponding to the position of the wafer W where the maximum film thickness value is detected and the pressure chamber corresponding to the position of the wafer W where the minimum film thickness value is detected (see step S504).

When controlling the pressure of the pressure chamber associated with the maximum film thickness value, the operation controller 9 controls the pressure of the pressure chamber so that the average film thickness value of the wafer W corresponding to the target pressure chamber is lower than the average film thickness value of the entire wafer W (see step S505A). When controlling the pressure of the pressure chamber associated with the minimum film thickness value, the operation controller 9 controls the pressure of the pressure chamber so that the average film thickness value of the wafer W corresponding to the target pressure chamber is higher than the average film thickness value of the entire wafer W (see step S505B).

Specifically, when controlling the pressure of the pressure chamber associated with the maximum film thickness value, the operation controller 9 calculates a target film thickness value that is reduced by a predetermined amount or by a predetermined percentage relative to the average film thickness value of the entire wafer W, and adjusts the pressure of the target pressure chamber so that the average film thickness value of the pressing area to which the measurement point of the maximum film thickness value belongs approaches the target film thickness value. More specifically, if the average film thickness value in the pressing area to which the measurement point of the maximum film thickness value belongs is higher than the target film thickness value, the operation controller 9 increases the pressure of the pressure chamber associated with the pressing area to which the measurement point of the maximum film thickness value belongs.

To reduce the film thickness range, the operation controller 9 may control only the pressure of the pressure chamber associated with the maximum film thickness value as described above, only the pressure of the pressure chamber associated with the minimum film thickness value as described above, or both the pressures of the pressure chamber associated with the maximum film thickness value and the minimum film thickness value. For the other pressure chambers, the operation controller 9 controls the other pressure chambers so that the difference between the average film thickness value of the corresponding pressing area and the average film thickness value of the entire wafer W is reduced.

With this configuration, when the film thickness range is outside the allowable range, the amount of polishing or the polishing speed within a certain period of time in the pressing area corresponding to the maximum film thickness value is larger than when the embodiment is not applied. The amount of polishing or the polishing speed within a certain period of time in the pressing area corresponding to the minimum film thickness value is smaller than when the embodiment is not applied. As a result, the polishing head 1 can keep the difference between the thickness in the thickest portion and the thickness in the thinnest portion of the entire wafer W within the desired allowable range.

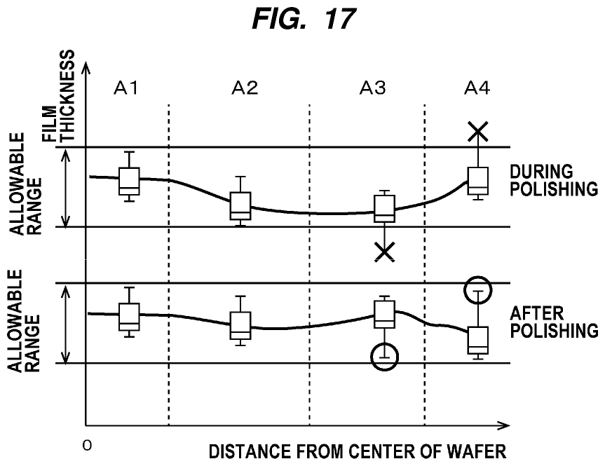

FIG. 17 is a view for explaining the effect of the polishing process according to another embodiment. In the embodiment shown in FIG. 17, the maximum film thickness value and the minimum film thickness value in the pressing areas A1 and A2 are within the allowable range during polishing the wafer W. Therefore, the operation controller 9 controls the respective pressures of the pressure chambers 70 and 71 corresponding to the respective pressure areas A1 and A2 so that the difference between the average film thickness values in the respective pressure areas A1 and A2 and the average film thickness value of the entire wafer W is reduced.

Since the minimum film thickness value in the pressing area A3 is outside the allowable range, the operation controller 9 controls the pressure in the pressure chamber 72 so that the average film thickness value in the pressure area A3 is higher than the average film thickness value of the entire wafer W. As a result, the amount of polishing in the pressing area A3 becomes small, and the polishing head 1 can keep the film thickness in the pressing area A3 within the allowable range.

Since the maximum film thickness value in the pressing area A4 is outside the allowable range, the operation controller 9 controls the pressure of the pressure chamber 73 so that the average film thickness value in the pressing area A4 is lower than the average film thickness value of the entire wafer W. As a result, the amount of polishing in the pressing area A4 is increased, and the polishing head 1 can keep the thickness of the film thickness in the pressure area A4 within the allowable range.

According to this embodiment, the operation controller 9 can keep the difference in film thickness of the wafer W surface within the allowable range based on the film thickness of the wafer W measured by the film thickness sensor 40 during polishing of the wafer W, without measuring the film thickness of the wafer W in advance.

If the film thickness range is still outside the allowable range in the pressing areas on the wafer W except for the pressing area on the wafer W corresponding to the maximum film thickness value and the pressing area on the wafer W corresponding to the minimum film thickness value, the operation controller 9 may perform a pressure control in such pressing areas as described above.

In one embodiment, the operation controller 9 may identify the maximum film thickness value and the minimum film thickness value on the wafer W based on the film thickness of the wafer W obtained at regular time intervals during polishing the wafer W. For example, if the rotational speed ratio (rotational speed of polishing table 3/rotational speed of polishing head 1) between polishing table 3 and polishing head 1 is 100/90 min⁻¹, then polishing table 3 rotates 10 times more than the polishing head 1 in 60 seconds.

With the above rotational speed ratio, the polishing table 3 rotates 10 times in 6 seconds and the polishing head 1 rotates 9 times in 6 seconds, so the relative positions of the polishing table 3 and polishing head 1 return to their original positions once in 6 seconds. Since the film thickness sensor 40 is embedded in the polishing table 3, the number of times the film thickness sensor 40 crosses over the surface of the wafer W depends on the rotation of the polishing table 3. Therefore, the movement path of the film thickness sensor 40 returns to its original position once every 6 seconds. Thus, the operation controller 9 may identify the maximum film thickness value and the minimum film thickness value based on the film thickness of the wafer W obtained during the time interval until the movement path of the film thickness sensor 40 returns to its original position.

In one embodiment, the operation controller 9 may identify the maximum film thickness value and the minimum film thickness value in each of the pressing areas A1, A2, A3, and A4 every time the polishing table 3 makes one rotation (i.e., every time the film thickness sensor 40 passes through one movement path), and control the respective pressures in the pressure chambers 70, 71, 72, and 73.

If the respective pressures of the pressure chambers 70, 71, 72, and 73 are controlled each time the film thickness sensor 40 passes through one movement path, the operation controller 9 may start the next pressure adjustment before the polishing by the controlled (adjusted) pressure progresses and is reflected in the film thickness change of the wafer W.

If the difference between the maximum film thickness value and the minimum film thickness value is calculated based on the results of film thickness measurements made within a certain period of time, and the associated pressure chamber pressure adjustments are made too frequently accordingly, the elastic film may not be controlled properly in relation to its pressure response and other factors. Therefore, the operation controller 9 should confirm the next film thickness range at certain intervals, allowing a period of time for the pressure adjustment of the pressure chamber to take effect. The operation controller 9 may also perform the film thickness measurement at the same measurement point again after the pressure adjustment to confirm the result of the pressure adjustment.

When the operation controller 9 identifies the maximum film thickness value and the minimum film thickness value, the polishing table 3 and the polishing head 1 are always rotating, and the polishing of the wafer W is always in progress. Therefore, for example, if the time interval is determined to be 6 seconds, in the relationship between the film thickness of the wafer W obtained in the first second and the film thickness of the wafer W obtained in the fifth second, the operation controller 9 will determine the film thickness obtained in the fifth second to be thinner than that obtained in the first second, and the actual film thickness uniformity cannot be evaluated accurately. Therefore, the operation controller 9 is configured to correct the film thickness value of the wafer W at each acquisition timing based on the polishing speed of the wafer W.

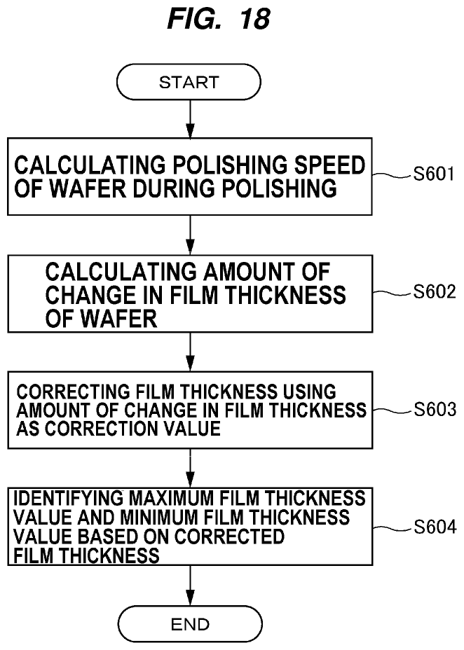

FIG. 18 is a view showing a flow of correcting the film thickness value by the operation controller. As shown in step S601 of FIG. 18, the operation controller 9 calculates the polishing speed of the wafer W from the film thickness of the wafer W obtained by the film thickness sensor 40 during polishing. Thereafter, the operation controller 9 calculates, based on the polishing speed of the wafer W, the amount of change in the film thickness of the wafer W between an obtaining time at which the film thickness of the wafer W is obtained by the film thickness sensor 40 at each measurement point of the wafer W and a predetermined reference time (see step S602).

The operation controller 9 corrects the film thickness of the wafer W obtained during polishing of the wafer W at a certain time interval using the amount of change in film thickness as a correction value (see step S603). For example, when the reference time is set as a start time of the above time interval, i.e., 0 second, the film thickness of the wafer W gradually decreases from the reference time, and the operation controller 9 corrects the film thickness of the wafer W by adding the amount of decrease in the film thickness as the correction value to the film thickness of the wafer W obtained during polishing.

Conversely, when the reference time is set as an end time of the above time interval (6 seconds in the above described embodiment), the film thickness of the wafer W is measured to be thicker than the film thickness at the reference time, so the operation controller 9 subtracts the amount of change of the film thickness as the correction value from the film thickness of the wafer W obtained during polishing. It is arbitrarily determined whether the reference time is the start time of the above time interval or a time in between.

After step S603, the operation controller 9 identifies the maximum film thickness value and the minimum film thickness value based on the corrected film thickness of the wafer W (see step S604). After step S604, the operation controller 9 controls the pressure of the pressure chambers 70, 71, 72, and 73 as in the pressure control flow shown in FIG. 16.

The above described embodiment describes a case in which the pressure chamber associated with the maximum film thickness value and the pressure chamber associated with the minimum film thickness value are separate (or different) pressure chambers, but the pressure chamber associated with the maximum film thickness value and the pressure chamber associated with the minimum film thickness value may be the same pressure chamber. In this case, the operation controller 9 may determine in advance by polishing recipe settings whether to control the pressure of the target pressure chamber so that the average film thickness value of the wafer W corresponding to the pressure chamber is lower than the average film thickness value of the entire wafer W, or to control the pressure of the target pressure chamber so that the average film thickness value of the wafer W corresponding to the pressure chamber is higher than the average film thickness value of the entire wafer W.

In one embodiment, if the pressure chamber associated with the maximum film thickness value and the pressure chamber associated with the minimum film thickness value are the same pressure chamber, the operation controller 9 may calculate a first difference between the maximum film thickness value and the average film thickness value of the entire wafer W and a second difference between the minimum film thickness value and the average film thickness value of the entire wafer W.

The operation controller 9 may compare the first difference with the second difference, and if the first difference is greater than the second difference, control the pressure of the target pressure chamber so that the average film thickness value of the wafer W corresponding to the pressure chamber associated with the maximum film thickness value is less than the average film thickness value of the entire wafer W. If the second difference is greater than the first difference, the operation controller 9 may control the pressure of the target pressure chamber so that the average film thickness value of the wafer W corresponding to the pressure chamber associated with the minimum film thickness value is greater than the average film thickness value of the entire wafer W.

In the embodiment described above, the difference between the maximum film thickness value and the average film thickness value of the entire wafer W is the first difference, and the difference between the minimum film thickness value and the average film thickness value of the entire wafer W is the second difference. However, the difference between the maximum film thickness value and the average film thickness in the pressing area corresponding to the maximum film thickness value may be the first difference, and the difference between the minimum film thickness value and the average film thickness in the pressing area corresponding to the minimum film thickness value may be the second difference.

In the embodiment described above, the operation controller 9 determines whether the difference (film thickness range) between the maximum film thickness value and the minimum film thickness value is within the desired (predetermined) allowable range, and adjusts the pressure in the pressure chamber associated with the maximum film thickness value and/or the pressure in the pressure chamber associated with the minimum film thickness value if the different is outside the allowable range. In one embodiment, the operation controller 9 may adjust the pressure of the pressure chamber associated with the maximum film thickness value and/or the pressure in the pressure chamber associated with the minimum film thickness value without comparing the difference between the maximum film thickness value and the minimum film thickness value and the allowable range. Thereby also, the pressure of the pressure chamber is controlled so that the average film thickness value in the pressing area associated with the maximum film thickness value is lower than the average film thickness value of the entire wafer W, and the pressure of the pressure chamber is controlled so that the average film thickness value in the pressure area associated with the minimum film thickness value is higher than the average film thickness value of the entire wafer W. As a result, the difference between the maximum film thickness value and the minimum film thickness value is reduced, and the uniformity of the film thickness of the wafer W can be improved.

The above embodiments are described for the purpose of practicing the present invention by a person with ordinary skill in the art to which the invention pertains. Although preferred embodiments have been described in detail above, it should be understood that the present invention is not limited to the illustrated embodiments, but many changes and modifications can be made therein without departing from the appended claims.

### INDUSTRIAL APPLICABILITY

The invention is applicable to a polishing apparatus and a polishing method.

### REFERENCE SIGNS LIST

1 polishing head
2 polishing pad
2a polishing surface
3 polishing table
5 polishing liquid supply nozzle
6 table motor
7 optical sensor head
9 operation controller
9a memory
9b processer
10 head shaft
21 head main body
25 rotary joint
40 film thickness sensor
44 light source
47 spectrometer
60 retaining ring
60a lower surface
60b upper surface
62 drive ring
65 elastic membrane
65a substrate pressing surface
70 central pressure chamber
71 intermediate pressure chamber
72 intermediate pressure chamber
73 edge pressure chamber
80 retaining ring pressing device
81 piston
82 rolling diaphragm
83 retaining ring pressure chamber
151 notch detection device
152 rotary encoder
170 film thickness measuring device

What is claimed is:

1. A polishing apparatus, comprising:
a polishing table supporting a polishing pad;
a polishing head having a plurality of concentrically divided pressure chambers, for pressing a substrate against the polishing surface of the polishing pad;
a plurality of pressure regulators coupled to the pressure chambers;
a film thickness sensor embedded in the polishing table, the film thickness sensor being configured to output a signal corresponding to a film thickness of the substrate; and
an operation controller configured to control a pressure of each of the pressure chambers individually through the pressure regulators,
wherein the operation controller is configured to:
obtain information related to a specific position, which is a part of a circumference of the substrate, and calculate a control target film thickness value in a control target area including the specific position and an average film thickness value of the entire substrate; and
control the pressure in the pressure chamber of the polishing head corresponding to the specific position so that a difference between the control target film thickness value and the average film thickness value of the entire substrate is reduced.

2. The polishing apparatus according to claim 1, wherein the operation controller is configured to identify the specific position based on a film thickness of the substrate measured before polishing.

3. The polishing apparatus according to claim 1, wherein the operation controller is configured to:
determine a maximum film thickness position at which a maximum film thickness value is obtained and a minimum film thickness position at which a minimum film thickness value is obtained, based on a film thickness of the substrate measured before polishing; and
determine at least one of the maximum film thickness position and the minimum film thickness position as the specific position.

4. The polishing apparatus according to claim 1, wherein the operation controller is configured to:
determine a maximum film thickness value and a minimum film thickness value based on the film thickness of the substrate measured before polishing;
calculate a difference between the average film thickness value of the entire substrate and the maximum film thickness value, and a difference between the average film thickness value of the entire substrate and the minimum film thickness value; and
determine a position on the substrate where the film thickness value with a largest difference is obtained as the specific position.

5. The polishing apparatus according to claim 1, wherein the control target film thickness value corresponds to at least one of the maximum film thickness value and the minimum film thickness value determined based on the film thickness of the substrate measured before polishing.

6. The polishing apparatus according to claim 1, wherein the control target film thickness value is an average value of the film thickness values within the control target area.

7. The polishing apparatus according to claim 1, wherein the operation controller is configured to:
measure a film thickness of the control target area including the specific position during polishing based on the signal output from the film thickness sensor; and
control the pressure in the pressure chamber of the polishing head corresponding to the specific position based on the measured film thickness.

8. The polishing apparatus according to claim 1, wherein the operation controller is configured to:
divide a plurality of pressing areas on the substrate divided corresponding to the pressure chambers into a specific pressing area including the control target area and an other pressing area excluding the specific pressure area;
calculate an average film thickness value in the other pressing area based on the film thickness of the substrate; and
control the pressure in the pressure chamber corresponding to the other pressing area so that a difference between the average film thickness value in the other pressing area and the average film thickness value of the entire substrate is reduced.

9. The polishing apparatus according to claim 1, wherein the operation controller is configured to:
obtain information related to a reference position, which is a part of the circumference of a reference substrate that is different from the substrate;
detect physical quantities corresponding to the film thickness of an area on the substrate including the reference position by the film thickness sensor during polishing of the reference substrate;
obtain a plurality of data corresponding to the film thickness of the reference substrate based on a plurality of signals sent from the film thickness sensor; and
associate each of data with the film thickness of the reference substrate when obtaining each of data.

10. The polishing apparatus according to claim 9, wherein the operation controller is configured to determine the reference position based on the film thickness of the reference substrate measured before polishing.

11. The polishing apparatus according to claim 1, wherein the operation controller is configured to control at least one of a rotational speed of the polishing head and a rotational speed of the polishing table so that the film thickness sensor crosses the control target area.

12. The polishing apparatus according to claim 11, wherein the operation controller is configured to:
determine a reference position and a relative angle of the polishing head based on a relationship between the reference position of a circumferential angle of the substrate and the rotational angle of the polishing head; and
control at least one of the rotational speed of the polishing head and the rotational speed of the polishing table based on the determined relative angle.

13. A polishing method of pressing a substrate on a polishing surface of a polishing pad by a polishing head having a plurality of concentrically divided pressure chambers, comprising:
obtaining information related to a specific position, which is a part of a circumference of the substrate, and calculating a control target film thickness value in a control target area including the specific position and an average film thickness value of the entire substrate;
controlling a pressure in the pressure chamber of the polishing head corresponding to the specific position so that a difference between the target film thickness value and the average film thickness value of the entire substrate is reduced.

14. The polishing method according to claim 13, comprising identifying the specific position based on a film thickness of the substrate measured before polishing.

15. The polishing method according to claim 13, comprising:
determining a maximum film thickness position at which a maximum film thickness value is obtained and a minimum film thickness position at which a minimum film thickness value is obtained based on a film thickness of the substrate measured before polishing; and
determining at least one of the maximum film thickness position and the minimum film thickness position as the specific position.

16. The polishing method according to claim 13, comprising:
determining a maximum film thickness value and a minimum film thickness value based on a film thickness of the substrate measured before polishing;
calculating a difference between the average film thickness value of the entire substrate and the maximum film thickness value, and a difference between the average film thickness value of the entire substrate and the minimum film thickness value; and
determining a position on the substrate where the film thickness value with a largest difference is obtained as the specific position.

17. The polishing method according to claim 13, wherein the control target film thickness value corresponds to at least one of a maximum film thickness value and a minimum film thickness value determined based on a film thickness of the substrate measured before polishing.

18. The polishing method according to claim 13, wherein the control target film thickness value is an average value of the film thickness values within the control target area.

19. The polishing method according to claim 13, comprising:
measuring a film thickness of the control target area including the specific position during polishing based on an output signal of the film thickness sensor; and
controlling a pressure in the pressure chamber of the polishing head corresponding to the specific position based on the measured film thickness.

20. The polishing method according to claim 13, comprising:
dividing a plurality of pressing areas on the substrate divided corresponding to the pressure chambers into a specific pressing area including the control target area and another pressing area excluding the specific pressing area;
calculating an average film thickness value in the other pressing area based on the film thickness of the substrate; and
controlling the pressure in the pressure chamber corresponding to the other pressure area so that a difference between the average film thickness value in the other pressure area and the average film thickness value of the entire substrate is reduced.

21. The polishing method according to claim 13, comprising:
obtaining information related to a reference position, which is a part of a circumference of a reference substrate that is different from the substrate;
detecting physical quantities corresponding to a film thickness of an area on the substrate including the reference position by the film thickness sensor during polishing of the reference substrate;
obtaining a plurality of data corresponding to the film thickness of the reference substrate based on a plurality of signals sent from the film thickness sensor; and
associating each of data with the film thickness of the reference substrate when obtaining each of data.

22. The polishing method according to claim 21, comprising determining the reference position based on the film thickness of the reference substrate measured before polishing.

23. The polishing method according to claim 13, comprising controlling at least one of a rotational speed of the polishing head and a rotational speed of the polishing table so that the film thickness sensor crosses the control target area by rotating of the polishing table that supports the polishing pad.

24. The polishing method according to claim 23, comprising:
determining a reference position and a relative angle of the polishing head based on a relationship between the reference position of a circumferential angle of the substrate and a rotational angle of the polishing head; and
controlling at least one of the rotational speed of the polishing head and the rotational speed of the polishing table based on the determined relative angle.

25. A polishing apparatus, comprising:
a polishing table supporting a polishing pad;
a polishing head having a plurality of concentrically divided pressure chambers, for pressing a substrate against a polishing surface of the polishing pad;
a plurality of pressure regulators coupled to the pressure chambers;
a film thickness sensor embedded in the polishing table, the film thickness sensor outputting a signal corresponding to a film thickness of the substrate; and
an operation controller configured to control a pressure of each of the pressure chambers individually through the pressure regulators,
wherein the operation controller is configured to:
identifying a maximum film thickness value and a minimum film thickness value from the film thickness of the substrate obtained during polishing of the substrate by the film thickness sensor;
identifying at least one of a pressure chamber corresponding to a position of the substrate at which the maximum film thickness value is detected and a pressure chamber corresponding to a position of the substrate at which the minimum film thickness value is detected;
controlling the pressure of the pressure chamber associated with the maximum film thickness value so that the average film thickness value of the substrate corresponding to the pressure chamber associated with the maximum film thickness value is less than the average film thickness value of the entire substrate when controlling the pressure of the pressure chamber associated with the maximum film thickness value; and
controlling the pressure of the pressure chamber associated with the minimum film thickness value so that the average film thickness value of the substrate corresponding to the pressure chamber associated with the minimum film thickness value is higher than the average film thickness value of the entire substrate when controlling the pressure of the pressure chamber associated with the minimum film thickness value.

26. The polishing apparatus according to claim 25, wherein the operation controller is configured to identify the maximum film thickness value and the minimum film thickness value based on the film thickness of the substrate obtained at regular time intervals during polishing the substrate.

27. The polishing apparatus according to claim 26, wherein the operation controller is configured to:
calculating a polishing speed during polishing from the film thickness of the substrate obtained by the film thickness sensor;
calculating the amount of change in the film thickness of the substrate between an obtaining time when the film thickness of the substrate is obtained by the film thickness sensor at each measurement point of the substrate and a reference time, based on the polishing speed;
correcting the film thickness of the substrate obtained during polishing of the substrate in the time intervals using the amount of change as a correction value; and
identifying the maximum film thickness value and the minimum film thickness value based on the corrected film thickness of the substrate.

28. The polishing apparatus according to claim 25, wherein the operation controller is configured to determine in advance by a recipe setting whether to control the pressure of the pressure chamber associated with the maximum film thickness value so that the average thickness value of the substrate corresponding to the pressure chamber associated with the maximum thickness value is less than the average thickness value of the entire substrate, or to control the pressure of the pressure chamber associated with the minimum film thickness value so that the average thickness value of the substrate corresponding to the pressure chamber associated with the minimum film thickness value is higher than the average thickness value of the entire substrate, when the pressure chamber associated with the maximum film thickness value and the pressure chamber associated with the minimum film thickness value are the same pressure chamber.

29. The polishing apparatus according to claim 25, wherein the operation controller is configured to:
compare a first difference between the maximum film thickness value and the average film thickness value of the entire substrate and a second difference between the minimum film thickness value and the average film thickness value of the entire substrate when the pressure chamber associated with the maximum film thickness value and the pressure chamber associated with the minimum film thickness value are the same pressure chamber;
control the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and
control the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

30. The polishing apparatus according to claim 25, wherein the operation controller is configured to:
compare a first difference between the maximum film thickness value and an average film thickness value in a pressing area corresponding to the maximum film thickness value and the second difference between the minimum film thickness value and the average film thickness value in the pressing area corresponding to the minimum film thickness value when the pressure chamber associated with the maximum film thickness value and the pressure chamber associated with the minimum film thickness value are the same pressure chamber;
control the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and
control the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

31. A polishing method of pressing a substrate on a polishing surface of a polishing pad by a polishing head having a plurality of concentrically divided pressure chambers, comprising:
identifying a maximum film thickness value and a minimum film thickness value from a film thickness of the substrate obtained during polishing of the substrate;
identifying at least one of a pressure chamber corresponding to a position of the substrate at which the maximum film thickness value is detected and a pressure chamber corresponding to a position of the substrate at which the minimum film thickness value is detected;
controlling the pressure of the pressure chamber associated with the maximum film thickness value so that the average film thickness value of the substrate corresponding to the pressure chamber associated with the maximum film thickness value is less than the average film thickness value of the entire substrate when controlling the pressure of the pressure chamber associated with the maximum film thickness value; and
controlling the pressure of the pressure chamber associated with the minimum film thickness value so that the average film thickness value of the substrate corresponding to the pressure chamber associated with the minimum film thickness value is higher than the average film thickness value of the entire substrate when controlling the pressure of the pressure chamber associated to the minimum film thickness value.

32. The polishing method according to claim 31, comprising identifying the maximum film thickness value and the minimum film thickness value based on the film thickness of the substrate obtained at regular time intervals during polishing the substrate.

33. The polishing method according to claim 32, comprising:
calculating a polishing speed during polishing from the film thickness of the substrate;
calculating the amount of change in the film thickness of the substrate between an obtaining time when the film thickness of the substrate is obtained at each measurement point of the substrate and a reference time, based on the polishing speed;
correcting the film thickness of the substrate obtained during polishing of the substrate in the time intervals using the amount of change as a correction value; and
identifying the maximum film thickness value and the minimum film thickness value based on the corrected film thickness of the substrate.

34. The polishing method according to claim 31, comprising: determining in advance by a recipe setting whether to control the pressure of the pressure chamber associated with the maximum film thickness value so that the average thickness value of the substrate corresponding to the pressure chamber associated with the maximum thickness value is less than the average thickness value of the entire substrate when the pressure chamber associated with the maximum film thickness value and the pressure chamber associated with the minimum film thickness value are the same pressure chamber, or to control the pressure of the pressure chamber associated with the minimum film thickness value so that the average thickness value of the substrate corresponding to the pressure chamber associated with the minimum film thickness value is higher than the average thickness value of the entire substrate.

35. The polishing method according to claim 31, comprising:
comparing a first difference between the maximum film thickness value and the average film thickness value of the entire substrate and a second difference between the minimum film thickness value and the average film thickness value of the entire substrate when the pressure chamber associated with the maximum film thickness value and the pressure chamber associated with the minimum film thickness value are the same pressure chamber;
controlling the pressure of the pressure chamber associated with the maximum film thickness value so that the average film thickness value of the substrate corresponding to the pressure chamber associated with the maximum film thickness value is lower than the average film thickness value of the entire substrate when the first difference is higher than the second difference; and
controlling the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

36. The polishing method according to claim 31, comprising:
comparing a first difference between the maximum film thickness value and an average film thickness value in the pressing area corresponding to the maximum film thickness value and the second difference between the minimum film thickness value and the average film thickness value in the pressing area corresponding to the minimum film thickness value when the pressure chamber associated with the maximum film thickness value and the pressure chamber associated with the minimum film thickness value are the same pressure chamber;
controlling the pressure of the pressure chamber associated with the maximum film thickness value so that the average film thickness value of the substrate corresponding to the pressure chamber associated with the maximum film thickness value is less than the average film thickness value of the entire substrate when the first difference is higher than the second difference; and
controlling the pressure of the pressure chamber associated with the minimum film thickness value so that the average film thickness value of the substrate corresponding to the pressure chamber associated with the minimum film thickness value is higher than the average film thickness value of the entire substrate when the second difference is higher than the first difference.

37. A polishing method of pressing a substrate against a polishing surface of a polishing pad by a polishing head having a plurality of pressure chambers including a specific pressure chamber, comprising:
a first polishing process of polishing the substrate under a first polishing condition; and
a second polishing process of polishing the substrate under a second polishing condition determined based on a first polishing profile along a radial direction of a specific area of the substrate corresponding to the specific pressure chamber, which is obtained by previously polishing a substrate different from the substrate under the first polishing condition,
wherein the second polishing condition comprises a polishing condition determined in advance to form a second polishing profile having a distribution opposite to the distribution of the first polishing profile, and
wherein the second polishing process is performed after the first polishing process.

38. The polishing method according to claim 37, wherein the specific pressure chamber comprises an edge pressure chamber configured to press against an outermost periphery of the substrate.

39. The polishing method according to claim 37, wherein the second polishing condition comprises a polishing condition determined by adjusting the pressure of a pressure chamber other than the specific pressure chamber.

40. The polishing method according to claim 37, wherein the second polishing condition comprises a polishing condition determined by adjusting the pressure of adjacent pressure chamber adjacent to an edge pressure chamber configured to press an outermost periphery of the substrate.

41. The polishing method according to claim 37, wherein the second polishing condition comprises a polishing condition determined by adjusting a pressing force of a retaining ring arranged around an outermost periphery of the substrate against the polishing surface.

42. The polishing method according to claim 37, wherein the first polishing condition comprises a polishing condition of polishing the substrate while feedback controlling the pressure of each of the pressure chambers based on the film thickness of the substrate corresponding to each of the pressure chambers, measured using a film thickness sensor, during polishing.

43. The polishing method according to claim 37, comprising polishing the substrate under the first polishing condition, and polishing the substrate under the second polishing condition after meeting a predetermined switching condition.

44. The polishing method according to claim 43, comprising switching from the first polishing condition to the second polishing condition, as the switching condition, when a difference between a maximum value and a minimum value of the film thicknesses in the specific area is larger than a predetermined threshold value.

45. The polishing method according to claim 43, comprising switching from the first polishing condition to the second polishing condition, as the switching condition, based on a time required to resolve a difference between a maximum value and a minimum value of the film thickness in the specific area by polishing under the second polishing condition and a remaining polishing time to a final target film thickness.

46. The polishing method according to claim 37, wherein the specific pressure chamber comprises an edge pressure chamber configured to press on an outermost periphery of the substrate, and
comprising controlling the pressure of the edge pressure chamber based on the second polishing condition, and controlling the pressure of an other pressure chamber except the edge pressure chamber based on the first polishing condition.
